(19) United States
(12) Patent Application Publication
(10) Pub. No.: US 2026/0101514 A1
(43) Pub. Date: Apr. 9, 2026

(54) NON-VOLATILE MEMORY DEVICE HAVING VERTICAL CHANNELS AND METHODS OF FABRICATION THEREOF

(71) Applicant: Infineon Technologies LLC, San Jose, CA (US)

(72) Inventors: Yanli ZHANG, San Jose, CA (US); Shivananda SHETTY, Fremont, CA (US); James PAK, Sunnyvale, CA (US); Shiraiwa HIDEHIKO, Battle Ground, WA (US); Liu ZHIZHENG, San Jose, CA (US)

(73) Assignee: Infineon Technologies LLC, San Jose, CA (US)

(21) Appl. No.: 18/907,252

(22) Filed: Oct. 4, 2024

(51) Int. Cl. H10B 43/30

(52) U.S. Cl. CPC H10B 43/30

(57) ABSTRACT

Semiconductor devices and methods of manufacturing the same are provided. The semiconductor devices may include a non-volatile memory (NVM) transistor form over a substrate having a buried lower source/drain (S/D) junction, an upper S/D junction, a vertical channel having a cylindrical shape disposed between the upper and lower S/D junctions, a cylindrical memory film stack surrounding the vertical channel, and a gate layer disposed around the memory film stack. The semiconductor devices may also include word lines surrounding the vertical channels, bit lines and source lines connecting multiple NVM transistors. Other embodiments are also described.

### CROSS-REFERENCE TO RELATED APPLICATIONS

None.

### TECHNICAL FIELD

This disclosure relates generally to semiconductor devices and more particularly to non-volatile memory (NVM) devices including memory cells with vertical channels and connection features thereof, embedded or integrally formed on a single or multiple substrates, and methods of fabrication the same.

### BACKGROUND

Non-volatile memory (NVM) is widely used for storing data in computer systems, and typically includes a memory array with a large number of NVM cells arranged in rows and columns, or other configurations. For the past several decades, the scaling of features in integrated circuits has been a driving force behind an ever-growing semiconductor industry. Scaling to smaller and smaller features enables increased densities of functional units on the limited real estate of semiconductor chips. The drive for ever-more capacity, however, is not without issue. Continued scaling of NVM devices, such as NOR flash memory, leads to word line (WL) pitch and bit line (BL)/source line (SL) pitch shrinkage. While scaling becomes increasingly significant, it may adversely affect the reliability of NVM devices by promoting breakdown voltage (BVdis) degradation, Icell degradation, and transient program disturb (TPD), amongst other potential defects.

It is, therefore, an object of the present disclosure to propose a NVM cell having a structure that decouples channel length from die size scaling and to optimize the performance while scaling becomes increasingly significant.

### BRIEF DESCRIPTION OF THE DRAWINGS

The present patent disclosure will be understood more fully from the detailed description that follows and from the accompanying drawings and the appended claims provided below, where:

FIG. 1 is a schematic diagram of a portion of an embodiment of an NVM device;

FIG. 2 a representative block diagram illustrating a cross-section of two NVM transistors or devices depicted in FIG. 1;

FIG. 3 is a schematic diagram of a portion of NVM device 200 according to an embodiment of the present disclosure;

FIG. 4 is a representative block diagram illustrating a top view of NVM device 200 according to an embodiment of the present disclosure;

FIG. 5A-5E are representative block diagrams each illustrating a cross-section of NVM device 200 according to an embodiment of the present disclosure;

FIG. 6 is a flowchart depicting a method of fabricating NVM device 200 having vertical channels according to an embodiment of the present disclosure;

FIG. 7A-7P are representative diagrams illustrating a portion of NVM device 200 at various points during its manufacture according to the method of fabrication of FIG. 6;

FIG. 8A-8B are flowcharts depicting methods of fabricating an NVM device 200 having vertical channels according to an embodiment of the present disclosure;

FIG. 9A-9D are representative diagrams illustrating a portion of NVM device 200 at various points during its manufacture according to the method of fabrication of FIG. 8B;

FIG. 10 is a schematic diagram of NVM device 1000 according to an embodiment of the present disclosure; and

FIG. 11 is a representative block diagram illustrating a top view of NVM device 1000 according to an embodiment of the present disclosure.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Before describing the various embodiments in more detail, further explanation shall be given regarding certain terms that may be used throughout the descriptions.

The term “etch” or “etching” is used herein to generally describe a fabrication process of patterning a material, such that at least a portion of the material remains after the etch is completed. For example, it should be understood that the process of etching silicon involves the steps of patterning a masking layer (e.g., photoresist or a hard mask) above the silicon, and then removing the areas of silicon no longer protected by the masking layer. As such, the areas of silicon protected by the mask would remain behind after the etch process is complete. However, in another example, etching may also refer to a process that may or may not use a mask, and may or may not leave behind a portion of the material after the etch process is complete.

The above description serves to distinguish the term “etching” from “removing.” When removing a material, substantially all of the material is removed in the process. However, in some embodiments, ‘removing’ is considered to be a broad term that may incorporate etching.

The term “CMP” is used herein to generally describe a chemical mechanical polishing or planarization process used to smooth a surface on or over a substrate during semiconductor fabrication. The process generally uses combination of an abrasive and/or corrosive colloidal slurry in conjunction with mechanical forces provided by affixing the substrate to a dynamic polishing head pressing it against a rotating a polishing pad. The process removes material from the substrate thereby providing a planarized surface.

During the descriptions herein, various regions of the substrate upon which the memory cell, logic and high voltage transistors or devices or connection features are fabricated are mentioned. It should be understood that any number of regions may exist on the substrate and may designate areas having certain, types of devices or materials. In general, the regions are used to conveniently describe areas of the substrate that include similar devices and should not limit the scope or spirit of the described embodiments.

The terms “over”, “overlying”, “under”, “between”, and “on” as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. Additionally, the relative position of one layer with respect to other layers is provided assuming operations deposit, modify and remove films relative to a starting substrate without consideration of the absolute orientation of the substrate.

The terms “deposit” or “dispose” are used herein to describe the act of applying a layer of material to the substrate. Such terms are meant to describe any possible layer-forming technique including, but not limited to, thermal growth, sputtering, evaporation, chemical vapor deposition, epitaxial growth, electroplating, etc. According to various embodiments, for instance, deposition may be performed according to any appropriate well-known method. For instance, deposition can comprise any process that grows, coats, or transfers material onto a substrate. Some well-known technologies include physical vapor deposition (PVD), chemical vapor deposition (CVD), electrochemical deposition (ECD), molecular beam epitaxy (MBE), atomic layer deposition (ALD), and plasma-enhanced CVD (PECVD), amongst others.

The “substrate” as used throughout the descriptions is most commonly thought to be silicon. However, the substrate may also be any of a wide array of semiconductor materials such as germanium, gallium arsenide, indium phosphide, etc. In other embodiments, the substrate may be electrically non-conductive such as a glass or sapphire wafer.

As used herein, “mask” may comprise any appropriate material that allows for selective removal (e.g., etching) of an unmasked portion a material. According to some embodiments, masking structures may comprise a photoresist such as Poly(methyl methacrylate) (PMMA), Poly(methyl glutarimide) (PMGI), a Phenol formaldehyde resin, a suitable epoxy, etc., or a hardmask including silicon nitride.

### SUMMARY OF SUBJECT MATTER

According to one embodiment of a semiconductor device, the semiconductor device may include a non-volatile memory (NVM) transistor form over a substrate that has a lower source/drain (S/D) junction buried at least partly in the substrate, an upper S/D junction, a vertical channel having a cylindrical shape disposed between the upper and lower S/D junctions, a cylindrical memory film stack surrounding the vertical channel, and a gate layer disposed around the memory film stack, a word line (WL) extending and coupling to gate layers of at least one NVM transistors in a first direction, wherein the gate layers of the at least one NVM transistors in the first direction may form a portion of the WL, a source line (SL) extending and coupling to lower S/D junctions of at least one NVM transistors in a second direction, wherein the lower S/D junctions of the at least one NVM transistors in the second direction form a portion of the SL, and a bit line (BL) extending and coupling to upper S/D junctions of at least one NVM transistors in the second direction, in which the first and second directions are substantially perpendicular to one another.

In one embodiment, the semiconductor device in which the vertical channel and the memory film stack may be disposed uprightly from a top surface of the substrate.

In one embodiment, the semiconductor device in which the vertical channel may have a circular cross-section and includes at least one of doped polysilicon or single-crystal silicon of a positive type, and wherein the lower and upper S/D junctions include at least one of polysilicon or single-crystal silicon doped with implant of a negative type.

In one embodiment, the semiconductor device in which the vertical channel may further include a channel filler including a dielectric layer surrounded by an outer channel shell including at least one of doped polysilicon or single-crystal silicon of a positive type.

In one embodiment, the semiconductor device in which the memory film stack may include a tunnel dielectric layer disposed adjacent to the vertical channel, a charge-trapping layer including at least one layer of silicon nitride or silicon oxynitride, and a blocking dielectric layer disposed overlying the charge-trapping layer.

In one embodiment, the semiconductor device in which the memory film stack may also include a ferroelectric film.

In one embodiment, the semiconductor device in which the charge-trapping layer may be configured to retain electrical charges in more than one physically and spatially separated regions, and in which the NVM transistors may be configured to store more than one bit of binary values.

In one embodiment, the semiconductor device in which the BL may be coupled to the upper S/D junction of the NVM transistor via a BL connect, wherein the BL connect may couple two neighboring NVM transistors to the BL.

In one embodiment, the semiconductor device in which the two neighboring NVM transistors may be respectively coupled to two neighboring SLs, in which the two neighboring SLs may be electrically insulated from one another.

In one embodiment, the semiconductor device in which the semiconductor device may be a bi-directional transistor device, and in which the lower and upper S/D junctions may be configured to function as both a source and a drain of the bi-directional transistor device.

In one embodiment, the semiconductor device in which the blocking dielectric layer may be surrounded by a high-K dielectric layer and the gate layer may include a layer of tungsten, making the semiconductor device a high-K metal gate device.

According to one embodiment of a non-volatile memory (NVM) array, the NVM array may include a plurality of source lines (SLs) buried within a substrate extending in a first direction, in which adjacent SLs may be insulated by shallow trench isolations (STIs), NVM transistors formed overlying the plurality of SLs, each NVM transistor including a lower source/drain (S/D) junction, a vertical channel surrounded by a memory film stack and a metal gate layer, and an upper S/D junction overlying the vertical channel, a plurality of word lines (WLs) coupling to the metal gate layers of at least one NVM transistors and extending in a second direction, in which the second direction is substantially perpendicular to the first direction, and a plurality of bit lines (BLs) overlying the upper S/D junctions and the metal gates of the NVM transistors, in which the BLs may be coupled to the upper S/D junctions of at least one NVM transistors and extend in the first direction.

In one embodiment, the NVM array in which the plurality of SLs may include doped polysilicon or single-crystal silicon, and in which lower S/D junctions of NVM transistors disposed overlying the same SL may form a portion of the same SL.

In one embodiment, the NVM array in which the plurality of WLs may include a metal layer, and in which metal gates of NVM transistors coupled by the same WL may form a portion of the same WL.

In one embodiment, the NVM array in which the first and second NVM transistors may be formed overlying two neighboring SLs, in which upper S/D junctions of the first and second NVM transistors may be coupled to a same BL via a horizontal BL connect.

In one embodiment, the NVM array in which the memory film stack may include a tunnel dielectric layer disposed adjacent to the vertical channel, a charge-trapping layer including at least one layer of silicon nitride or silicon oxynitride configured to retain electrical charges in more than one physically and spatially separated regions therein, and a blocking dielectric layer including a layer of high-K dielectric disposed overlying the charge-trapping layer.

In one embodiment, the NVM array in which the vertical channel may further include a channel filler including a dielectric layer surrounded by an outer channel shell including doped polysilicon or single-crystal silicon of a positive type, and in which the lower and upper S/D junctions may include polysilicon or single-crystal silicon doped with implant of a negative type.

According to one embodiment of a semiconductor device, the semiconductor device may include a plurality of non-volatile memory (NVM) transistors arranged in rows and columns formed in a substrate, in which each NVM transistor may include a lower source/drain (S/D) junction, a vertical channel surrounded by a memory film stack and a metal gate layer, and an upper S/D junction overlying the vertical channel, a plurality of word lines (WLs), each coupling NVM transistors of a same row, in which metal gate layers of the NVM transistors of the row may form a portion of the WLs, a plurality of source lines (SLs), each coupling NVM transistors of two adjacent columns, in which lower S/D junction of the NVM transistors of the two adjacent columns may form a portion of the SLs, and a plurality of bit lines (BLs), each coupling NVM transistors of at least one column via a plurality of BL connects, in which the plurality of NVM transistors may be formed overlying the plurality of SLs at least partly formed within the substrate, the plurality of SLs and BLs may propagate in the same direction, and the plurality of WLs and BLs may propagate in the perpendicular direction.

In one embodiment, the semiconductor device in which NVM transistors that are formed overlying the same SL may be coupled to two adjacent BLs, respectively.

In one embodiment, the semiconductor device in which the memory film stack may include a tunnel dielectric layer disposed adjacent to the vertical channel, a charge-trapping layer including at least one layer of silicon nitride or silicon oxynitride configured to retain electrical charges in more than one physically and spatially separated regions, and a blocking dielectric layer disposed overlying the charge-trapping layer.

In one embodiment, the semiconductor device may be a NOR flash memory device.

In one embodiment, the semiconductor device in which the plurality of NVM transistors may be arranged in one single layer between the BLs and SLs.

### DESCRIPTION OF EMBODIMENTS

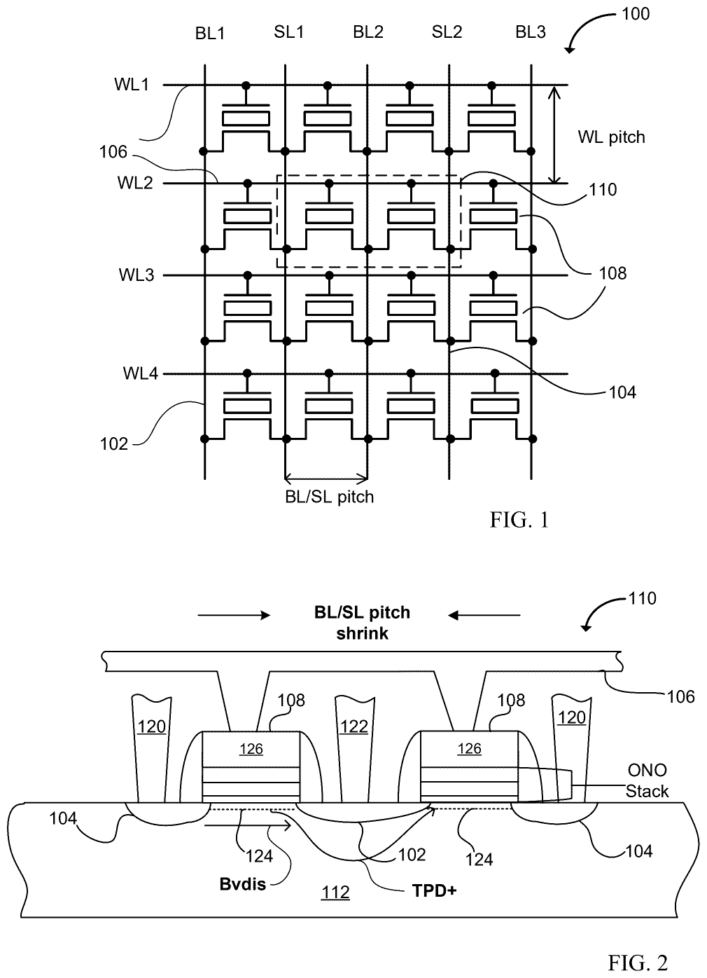

FIG. 1 illustrates a schematic block diagram of a portion of an NVM device 100 according to an embodiment. FIG. 2 illustrates a representative cross-section of two adjacent NVM transistors 108 along or connected to the same word line WL2 at each of its gates. In one embodiment, NVM device 100 includes NVM transistors 108 arranged in rows (horizontal) and columns (vertical), connected with word lines or regions (WLs) 106, bit lines or regions (BLs) 102, source lines or regions (SLs) 104, and/or other connections. In embodiments, NVM device 100 may be configured to function as NOR flash memory, EEPROM, or other types of non-volatile memory devices. It may also include one or more memory array(s) or be organized in multiple erase sectors. NVM transistors 108 may be field-effect transistors having a non-conducting charge-trapping layer(s) or a floating gate layer to trap charges. In some embodiments, NVM device 100 may be embedded in another semiconductor device or system, such as micro-controllers that includes MOSFETs and other semiconductor devices. As shown in FIG. 1, WLs 106 connect NVM transistors 108 extended or propagated in one direction and BLs 102 and SLs 104 connect NVM transistors 108 in an opposite direction. It would be the understanding that this particular arrangement is shown as an example and one having ordinary skill in the art would recognize other arrangements may be adopted. In embodiments, NVM transistors 108 may be a bi-directional device, capable of storing one or more bit(s) of binary information or bit values. In those configurations, BLs 102 and SLs 104 may be interchangeable functionally and referred to as BL/SLs collectively throughout this patent document.

As best shown in FIG. 2, NVM transistors 108 adopt a planar or two-dimensional (2D) structure in which channels 124 run horizontally or parallel to the substrate 112 surface between BL 102 to SL 104. It will be the understanding that, depending on the device design, BLs 102 and SLs 104 may also be doped regions within substrate 112, functionally performing as source or drain regions of NVM transistors 108. In embodiments, there may be BL connects 122 and SL connects 120 to complete the BLs 102 and SLs 104 connection. WLs 106 are coupled to gate 126 of NVM transistors and extend perpendicularly to BL/SLs.

One of the main challenges of scaling semiconductor devices, such as NVM device 100, is that the size of NVM transistors 108 is much reduced and packed closer together. The reduction in size may shorten the channel 124 length while densely packing NVM transistors 108 may reduce WL pitch and BL/SL pitch. The excessive scaling may adversely affect reliability and performance of the device by worsening transient program disturb (TPD+) of neighboring NVM transistors 108, breakdown voltage (BVdis) degradation, adjacent word line disturb (AWD), and sensing current (Icell) degradation, among other potential defects.

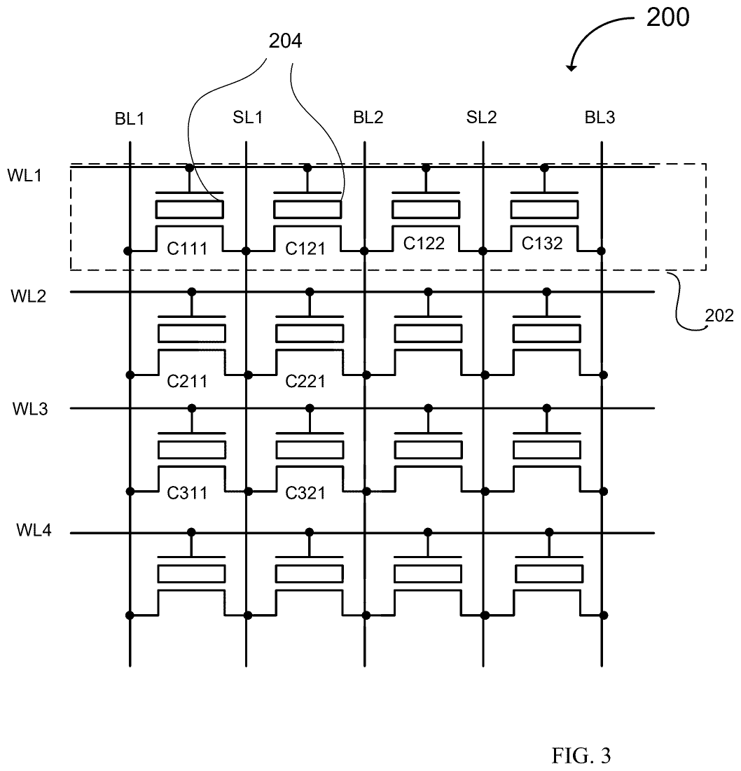

FIG. 3 is a schematic diagram illustrating a portion of NVM array 200 including multiple NVM cells 204 arranged in rows and columns. NVM cells 204, as will be shown and described in later sections, each includes a vertical channel disposed and extending between source/drain regions of the device. As best shown in FIG. 3, NVM cells 204 are connected along horizontal rows by word lines (WLs) and vertical columns by bit lines (BLs) and source lines (SLs). It would be the understanding that the terms “columns” and “rows” of NVM array 200 may be used interchangeably depending on the orientation of NVM array 200. It would also be the understanding that NVM cells 204 may be arranged and connected in other ways known by one having ordinary skill in the art, without deviating from the principle of this patent disclosure.

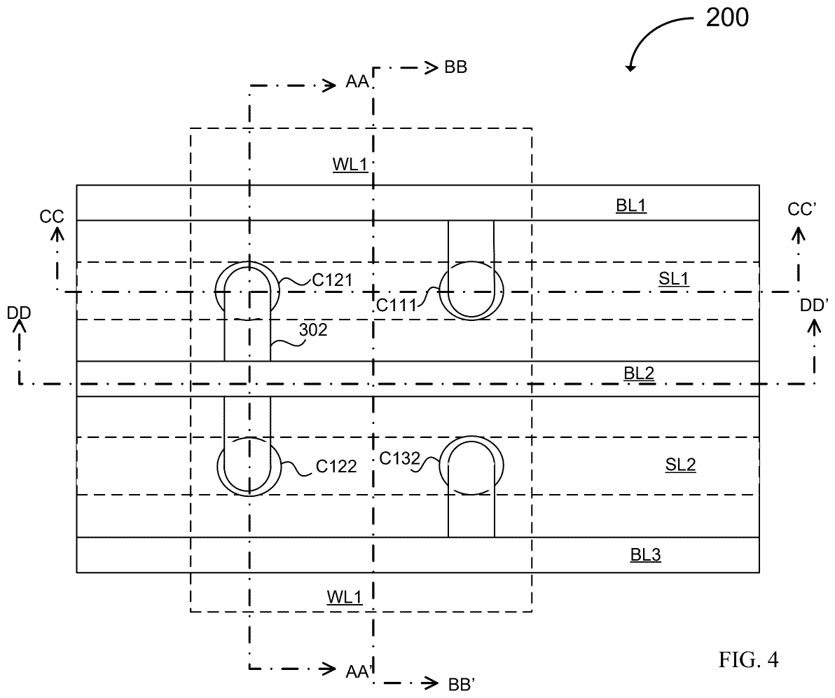

FIG. 4 is a block diagram illustrating a top view of section 202 of NVM array 200 (as best shown in FIG. 3) including four adjacent NVM cells C111, C121, C122, and C132, all along WL1. Each NVM cell adopts a cylindrical shape having a circular or an oval shaped planar cross-section. As best shown in FIGS. 3 and 4, C111 and C121 shares a source line SL1; and C122 and C132 shares an adjacent source line SL2. In one embodiment, source lines, such as SL1, are disposed underneath NVM cells 204 or buried within the substrate. BLs, such as BL1, are disposed above NVM cells 204 and are connected to NVM cells 204 via BL connects 302. As best shown in FIG. 4, NVM cell C111 is coupled to BL1 and NVM cells C121 and C122 are coupled to BL2 via their respective BL connects 302. In embodiments, NVM cells 204 are bi-directional devices in which current may run in both directions between SLs and BLs. Therefore, SLs and BLs may be functionally interchangeable and only physically or structurally distinguishable. In one embodiment, there is only one single layer of NVM cells disposed between SLs and BLs in NVM array 200.

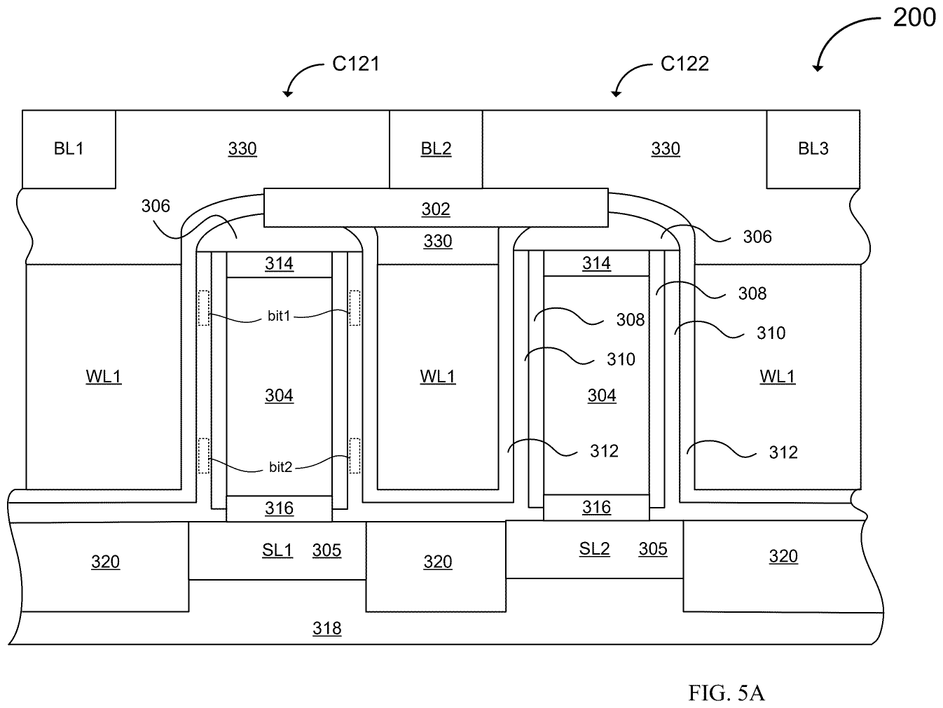

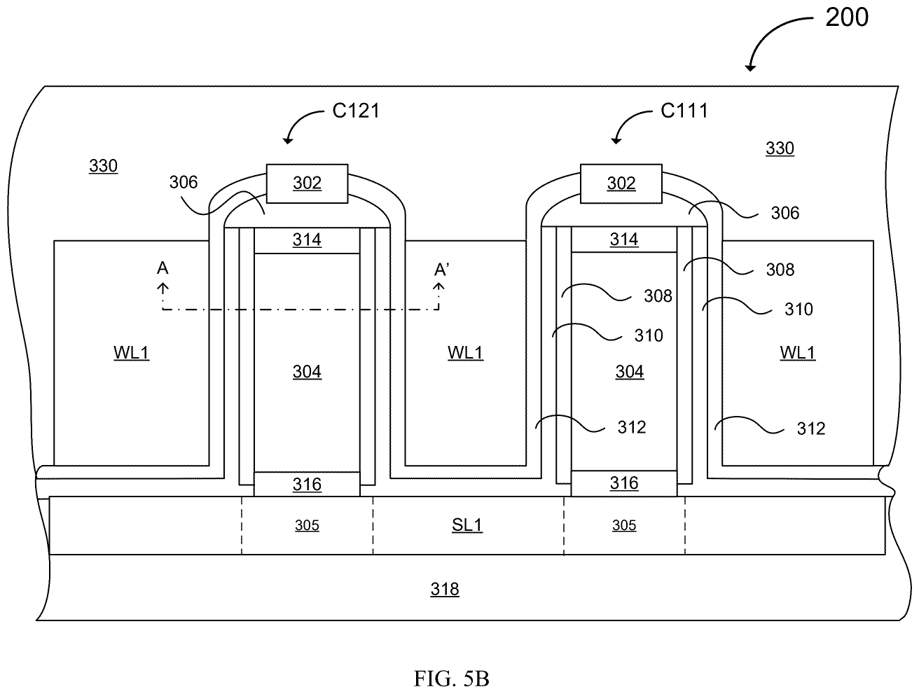

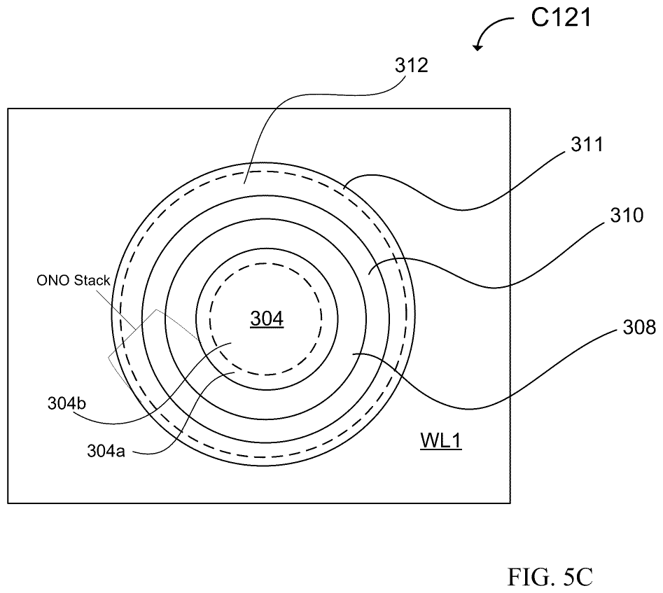

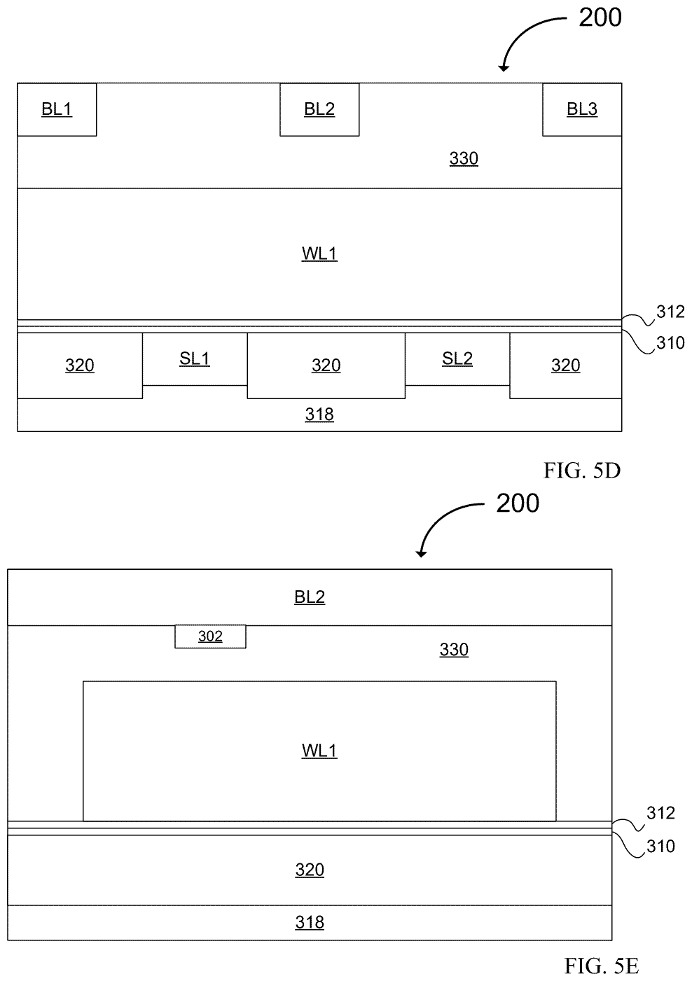

FIG. 5A is a representative block diagram illustrating a vertical cross-sectional view of NVM array 200 along cutting plane line AA-AA′ in FIG. 4. As best shown in FIG. 5A, NVM cell C121 and C122 are formed adjacent to one another over substrate 318. In one embodiment, NVM cell 204, such as C122, includes source line SL2 that includes heavily doped silicon or similar semiconductor material such as germanium, silicon-germanium or a Group III-V compound semiconductor material, formed within substrate 318 and upper source/drain (S/D) region 306, connected by vertical channel 304. Buried source lines, such as SL2, may serve a dual function of connecting NVM cells along a column or row as previously explained and acting as another source/drain region for NVM cells. Throughout this patent document, buried source lines may also be referred to as lower S/D region 305 of a NVM cell 204. In a bi-directional device, such as NVM cell 204, upper and lower S/D regions 306 and 305 may function as source or drain respectively in different operation settings. Within substrate 318, lower S/D regions 305 of adjacent NVM cells are electrically isolated by shallow trench isolation (STI) structures 320. In one embodiment, intervening structure upper lightly doped S/D 314 is formed between vertical channel 304 and upper S/D region 306. Similarly, lower lightly doped S/D 316 is formed between vertical channel 304 and lower S/D region 305. In one embodiment in which NVM cell is an n-channel device, upper and lower S/D regions 306 and 305 are doped heavily with n-type dopants including but not limited to arsenic and phosphorus while lower and upper lightly doped S/D 314 and 316 are made of lightly doped semiconducting material with the same or different n-type dopants. Vertical channels 304 adopt a cylindrical shape and may include semiconducting material such as silicon with p-type implants including but not limited to boron. One having ordinary skill in the art would recognize that dopants in upper and lower S/D regions 306 and 305, upper and lower lightly doped S/D 314 and 316, and vertical channels 304 may have dopants of different or opposite types when NVM cells 204 are p-channel devices. One of the advantages of having vertical channel, such as vertical channel 304, is that channel length may be independent from scaling of NVM cells, such as shrinkage of WL pitch and BL/SL pitch.

Still referring to FIG. 5A, cylindrical vertical channel 304 is surrounded by a memory film stack of three dielectric layers, viz. tunnel oxide layer 308, charge-trapping layer 310, and blocking dielectric layer 312, forming an ONO stack. In one embodiment, tunnel oxide layer 308 may include silicon oxide or other dielectric materials. Charge-trapping layer 310 may be single or multiple layered including silicon nitride, oxynitride, or combinations thereof, and trap charges injected from vertical channel 304. In another embodiment, instead of an ONO stack, the memory film stack may include one or more layers of ferroelectric film (not shown in FIG. 5A), including such as hafnium dioxide (HfO₂). Optionally having one or more layer of dielectric, such as silicon oxide or oxynitride, disposed between vertical channel 304 and the ferroelectric film as an interfacial film or layer. Threshold voltage (VT) and drain current (ID) values of NVM cell 204 may change at least partly due to the amount of trapped charges. Through proper biasing, NVM cell 204 can store one or more spatially separated physical bits (bit1 and bit2 as shown in NVM C121) as charges at opposite ends of the charge-trapping layer 310. These two independent physical bits (bit1 and bit2) can be independently read by running a current through the vertical channel 304 in different directions (bi-directional), or other read/sensing algorithms known by one having ordinary skill in the art. Blocking dielectric layer 312 may include silicon oxide and may be multi-layered including optionally a high K dielectric layer. The high-K dielectric layer may include but not limited to, aluminum oxide, hafnium oxide, zirconium oxide, hafnium silicate, hafnium oxy-nitride, hafnium zirconium oxide, and lanthanum oxide. As best shown in FIG. 5A, blocking dielectric layers 312 of NVM cells C111 and C121 are surrounded or partly encapsulated by WL1. In one embodiment, WL1 or in general all WLs of NVM array 200 serve two functions. First, similar to WLs 106 in FIGS. 1 and 2, WLs of NVM array 200 connects NVM cells 204 at their respective gates of the same row or column, depending on the arrangement of NVM array 200. WLs of NVM array 200 also function as a gate of each NVM cell 204 of the same row or column. For instance, WL1 functions as a gate to NVM cells C121, C111, C122, and C132, as best shown in FIG. 4. In one embodiment, WLs of NVM array 200 may include one or more layer of polysilicon, aluminum, titanium, titanium-nitride, tungsten or compounds or alloys thereof. Adjacent NVM cells that share a common BL, such as C121 and C122 sharing BL2, are coupled at their respective upper S/D regions 306 by BL connect 302 to BL2. BL connect 302 may include conductive material including but not limited to one or more layer of aluminum, titanium, titanium-nitride, tungsten or compounds or alloys thereof. As best shown in FIG. 5A, NVM cells 204 and BLs such as BL1, BL2, BL3 are electrically insulated from one another by one or more interlevel dielectric (ILD) layer 330 that includes non-conductive or dielectric material such as silicon oxide, silicon nitride, or silicon oxynitride. In one embodiment, all NVM cells 204 of NVM array 200 are arranged in one single layer, disposed vertically between BLs and SLs, and having memory film stack portion surrounded by corresponding WLs.

FIG. 5B is a representative block diagram illustrating a vertical cross-sectional view of NVM array 200 along cutting plane line CC-CC′ in FIG. 4. As best shown in FIGS. 4 and 5B, NVM cells C121 and C111 are adjacent to one another, disposed along and over, and therefore share the common SL1. In one embodiment, SL1 functions as a source line connecting both NVM cells C121 and C111, as well as lower S/D regions 305 for both, respectively. As best shown in FIG. 5B, SL1 runs in a perpendicular direction (left and right) to WL1 (in and out).

FIG. 5C is a representative block diagram illustrating a horizontal cross-sectional view of NVM cell C121 along cutting plane line A-A′ in FIG. 5B. NVM cells 204, such as NVM cell C121 as shown, adopts a circular or oval cross-sectional shape. As best shown in FIG. 5C, vertical channel 304 is in the middle in which electric current/charges runs between upper and lower S/D regions 306 and 305. In one embodiment, vertical channel 304 may be formed with a single layer of doped or undoped semiconductor material, such as p-doped single crystal silicon, polysilicon, or other materials adopted for building channel of charge-trapping NVM transistors. In other embodiments, vertical channel 304 may adopt a macaroni channel configuration, including outer channel layer 304a and channel filler 304b. Outer channel layer 304a may include a single layer of doped semiconductor material, such as p-doped single crystal silicon, polysilicon, or other materials adopted for building channels of charge-trapping NVM transistors. Channel filler 304b may be formed by depositing a layer of dielectric material, such as silicon oxide or silicon oxynitride to fill the void. Vertical channel 304 is disposed adjacent to or surrounded by tunnel oxide layer 308. Tunnel oxide layer 308 is disposed adjacent to or surrounded by charge-trapping layer 310. Charge-trapping layer 310 is disposed adjacent to or surrounded by blocking dielectric layer 312. In one embodiment, tunnel oxide layer 308, charge-trapping layer 310, and blocking dielectric layer 312 form an oxide-nitride-oxide (ONO) stack, resembling the ONO stack in planar NVM transistor 108 shown in FIG. 2. It will be the understanding that each of layers in the ONO stack may be single or multiple-layered. The ONO stack is disposed adjacent to or surrounded by WL1 that functions as the metal gate to NVM cell C121. In embodiments, WL1 may turn NVM cells, such as NVM cell C121, on or off in various operations (such as read, program, erase, etc.) by appropriate biasing practiced by one having ordinary skill in the art. In one embodiment, blocking dielectric layer 312 may also include hi-K dielectric layer 311, making NVM cell C121 a hi-K metal gate (HKMG) device. In another embodiment, instead of the ONO stack, the memory film stack may include one or more layers of ferroelectric film, such as hafnium dioxide (HfO₂). Optionally having one or more layer of dielectric or interfacial layer, such as silicon oxide or oxynitride, disposed between vertical channel 304 and the ferroelectric film (not shown in FIG. 5C).

FIG. 5D is a representative block diagram illustrating a vertical cross-sectional view of NVM array 200 along cutting plane line BB-BB′ in FIG. 4. As best shown in FIG. 5D, BLs such as BL1, BL2, and BL3, are electrically and physically isolated from each other and from WLs, such as WL1, by ILD layer 330. In one embodiment, cutting plane line BB-BB′ does not intersect with any NVM cells 204. WL1 is also electrically and physically isolated from SL1, SL2, and substrate 318 by two dielectric layers 312 and 310. As best shown in FIG. 5B, WL1 runs in a perpendicular direction (left and right) to BLs and SLs (in and out).

FIG. 5E is a representative block diagram illustrating a vertical cross-sectional view of NVM array 200 along cutting plane line DD-DD′ in FIG. 4. As best shown in FIG. 5E, BL connector 302 that coupled NVM cells C121 and C122 to BL2 is electrically and physically isolated from WL1 by ILD layer 330. While running in the same direction (left and right), BLs and SLs (absent in this cross-sectional view) do not intersect in the same vertical plane.

Compared to conventional two-dimensional (2D) horizontal memory device, the channel of NVM device of the present embodiment, such as NVM cell 204, is vertical. One advantage of vertical channel devices is that area scaling is decoupled from channel scaling, which maintains breakdown voltage while always degrades in horizontal device scaling.

Another advantage is that vertical channels are separated from one another and sealed by SL, which largely eliminates transient program disturb that would have happened to adjacent horizontal devices. Yet another advantage is that gate all around features in the vertical channel device shield device channel and charge trapping layers from neighboring devices, and there is no adjacent WL disturb as for horizontal device. Yet another advantage is that vertical channel device sensing current is determined by the perimeter of the device channel, which gives more scaling margin compared to reducing device width in horizontal devices.

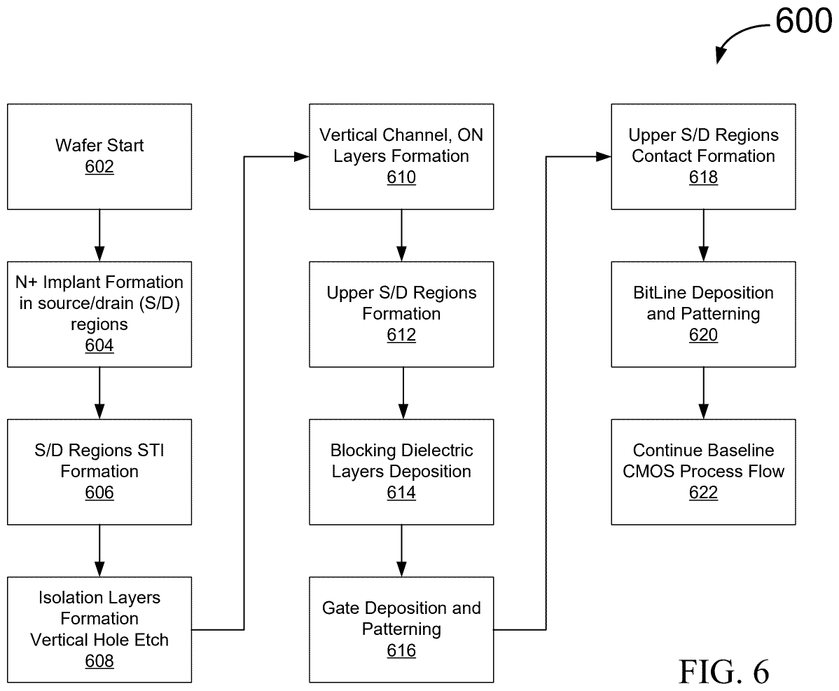

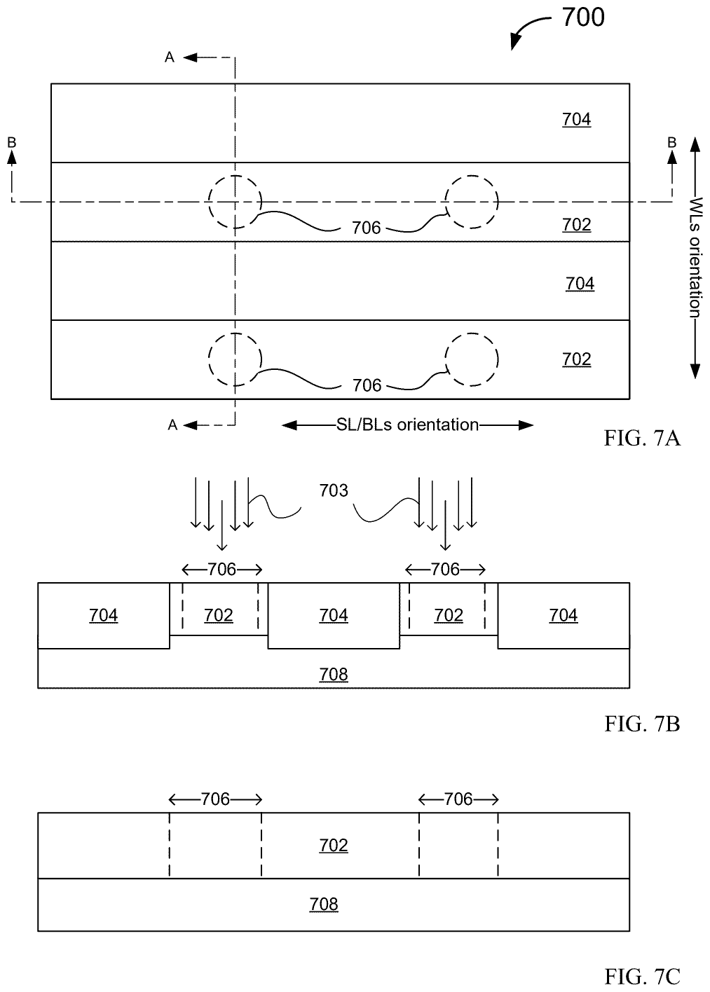

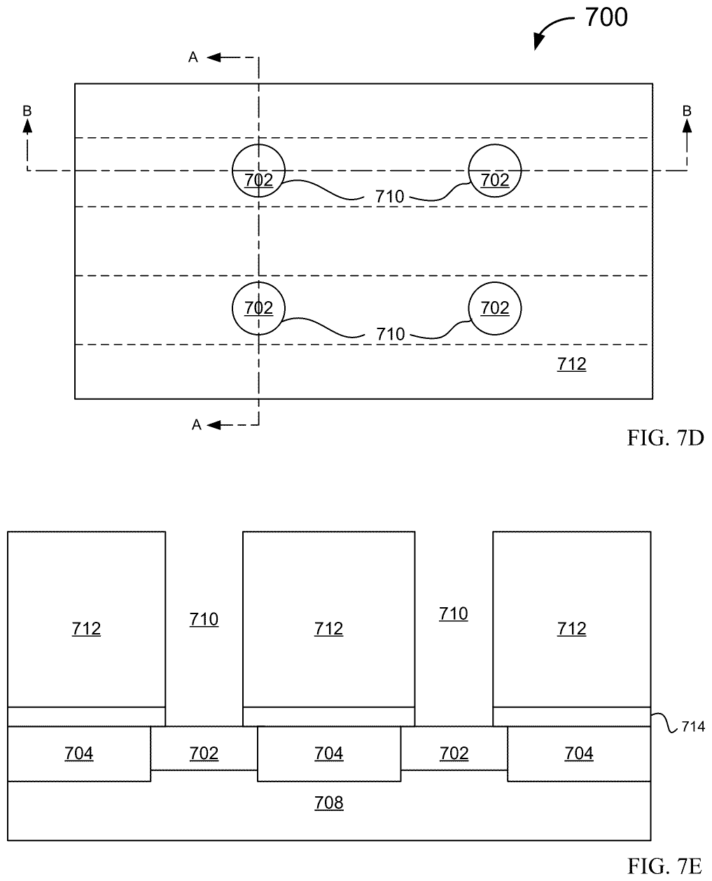

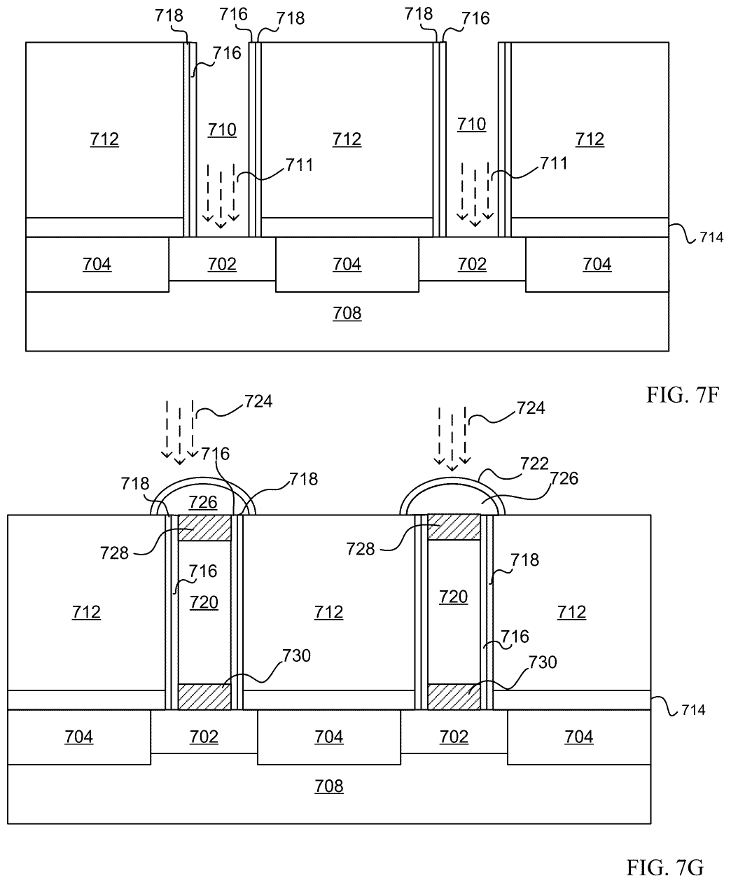

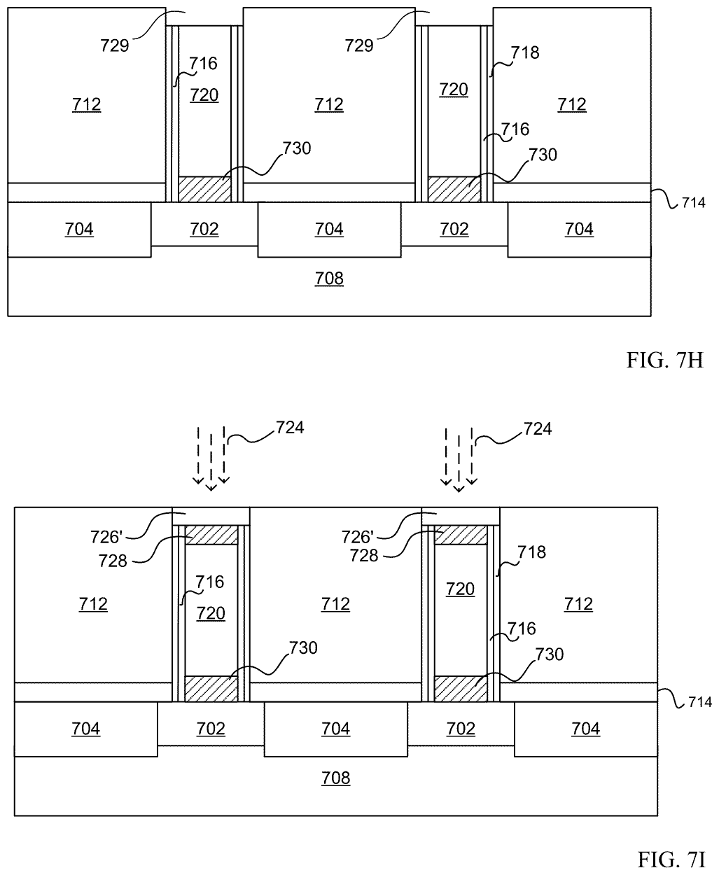

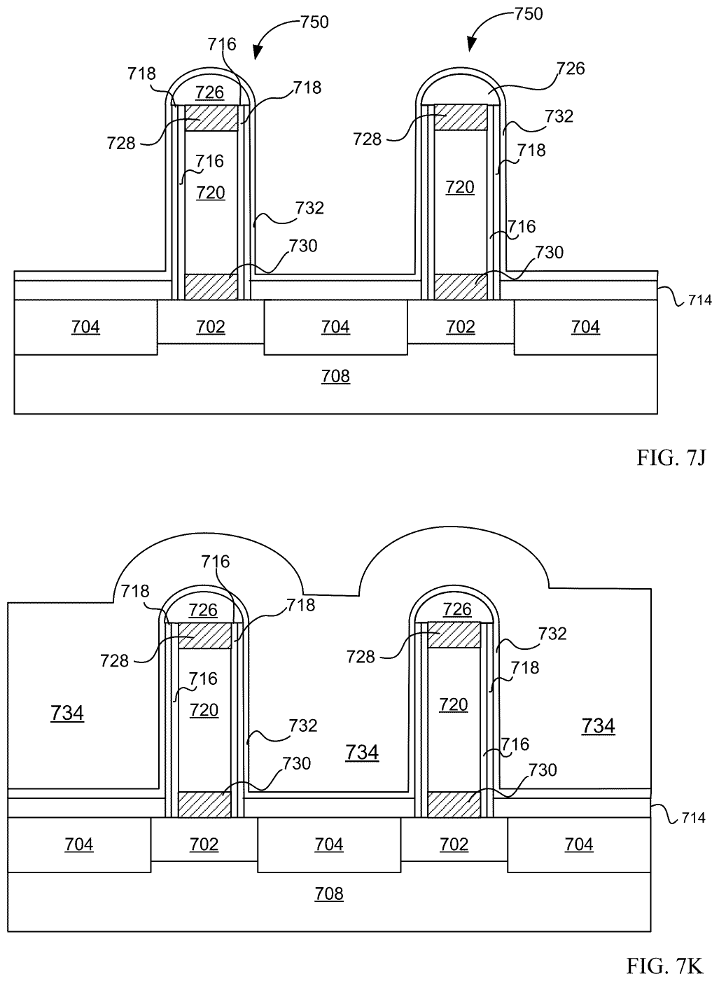

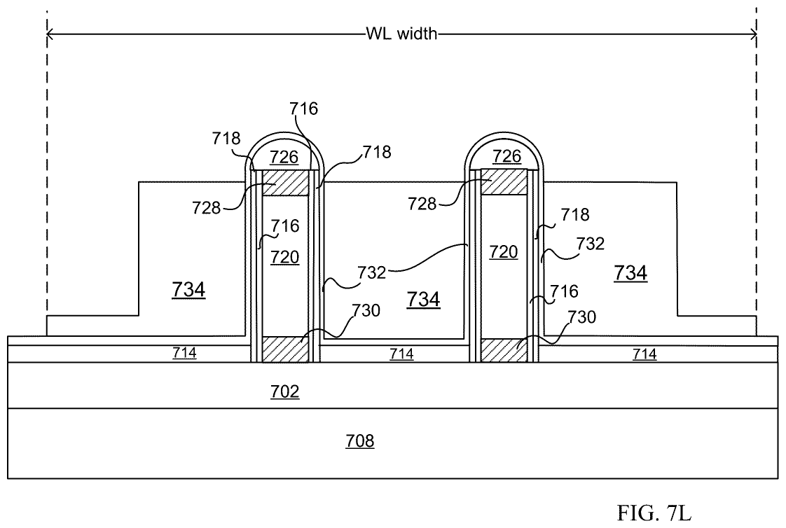

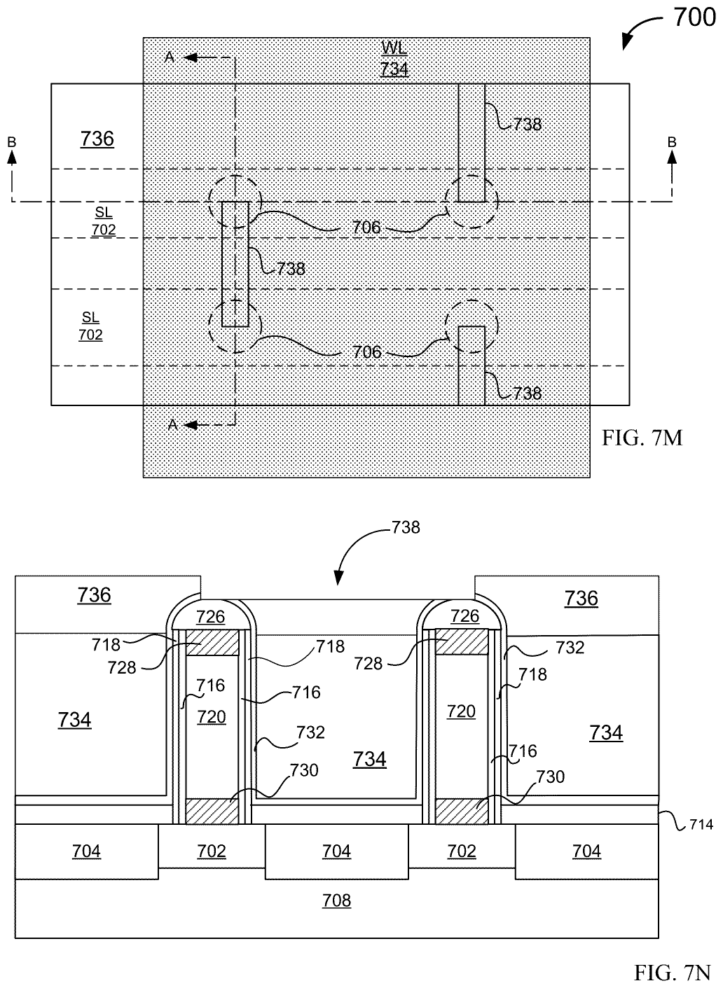

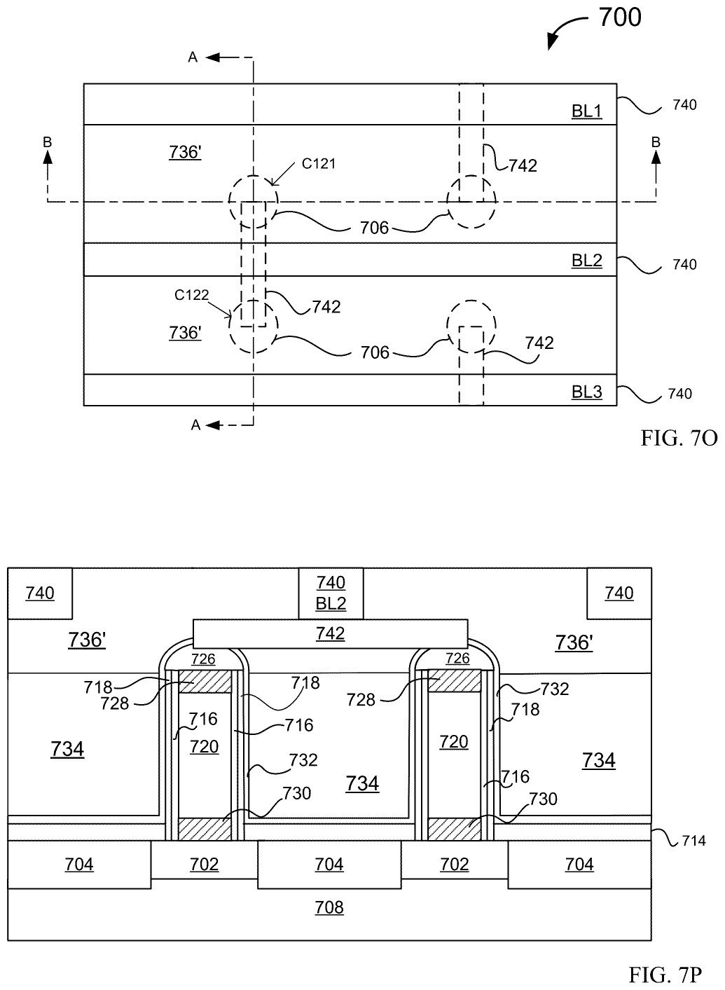

FIG. 6 is a flowchart depicting a method of fabricating NVM device 700 having vertical channels according to an embodiment of the present disclosure. FIG. 7A-7P are representative diagrams illustrating a portion of NVM device 700 at various points during its manufacture according to the method of fabrication of FIG. 6. In one embodiment, NVM device 700 may have similar configurations and structural features as NVM array 200, as best shown in FIGS. 3 and 4. In one embodiment, NVM device 700 is an n-type NVM device, such that NVM cells 706 are n-channel devices. It would be the understanding that fabrication process in this patent document may be modified to fabricate p-type NVM devices by adopting an opposite or different doping scheme, as practiced by one having ordinary skill in the art.

Referring to FIGS. 6 and 7A, the manufacturing process may begin with an optional pre-clean step of substrate 708 (step 602). FIG. 7A illustrates a representative top view of substrate 708, while FIGS. 7B and 7C each illustrates a representative vertical cross-sectional view along cutting plane A-A and B-B, of substrate 708 respectively. Referring to FIG. 7A, substrate 708 is divided into one or more isolation region(s) 704 and lower source/drain (S/D) region(s) 702. The substrate 708 may be a bulk substrate composed of any single crystal material suitable for semiconductor device fabrication, or may include a top epitaxial layer of a suitable material formed on a substrate. In one embodiment, suitable materials for substrate 708 include, but are not limited to, silicon, germanium, silicon-germanium or a Group III-V compound semiconductor material. As best shown in FIG. 7A, each region 702 and 704 resembles an elongated structure extending horizontally across substrate 708. Elongated structures of isolation region(s) 704 and lower source/drain region(s) 702 are disposed in alternate manner across substrate 708. As previously explained, lower S/D regions 702 may function as a source line connecting NVM cells 706 of the same column or row, depending on the orientation of NVM device 700. In one embodiment, NVM cells 706, as shown as footprints in FIG. 7A, would be fabricated within and overlying lower source/drain region(s) 702. Referring to FIGS. 6 and 7B, dopants are implanted into substrate 708 to form lower S/D regions or junctions 702 (step 604). The dopants 703 implanted may be of any type and concentration, and may be implanted at any energy, including energies necessary to form heavily doped negative implant (N+ implant). Negative dopant implants 703 may include arsenic ions, phosphorus ions, etc. It is further appreciated that lower S/D regions 702 may be formed by depositing and patterning a mask layer (not shown), such as a photoresist layer or a hard mask above surface of substrate 708, and implanting an appropriate ion species at an appropriate energy to an appropriate concentration. P-type dopant implants, such as boron ions may be used in p-type NVM cells, as would be practiced by one having ordinary skill in the art. As best shown in FIG. 7B, footprints of would be fabricated NVM cells 706 are disposed within lower S/D region(s). In one embodiment, lower S/D regions may be formed to a depth of an approximate range of 100 Å to 7500 Å.

Referring to FIGS. 6 and 7B, isolation regions 704 are formed to separate each of lower S/D region 702 both physically and electrically (step 606). In embodiments, isolation regions may include a dielectric material, such as oxide or nitride, and may be formed by any conventional technique, including but not limited to shallow trench isolation (STI) or local oxidation of silicon (LOCOS). Optionally, chemical mechanical planarization (CMP) may be performed to produce a level substrate surface for subsequent process(es). In embodiments, isolation regions 704 may be formed before, after, or concurrently with lower S/D regions 702, to a depth of an approximate range of 500 Å to 8000 Å. Subsequently and optionally, pad oxide (not shown) may be formed to cover the entire surface of substrate 708, including lower S/D regions 702 and isolation regions 704. Pad oxide may be silicon dioxide (SiO₂) having a thickness of from about 10 nanometers (nm) to about 20 nm or other thicknesses and may be grown by a thermal oxidation process or in-situ steam generation (ISSG) process, or other oxidation or deposition processes known in the art. It will be the understanding that pad oxide may not be necessary, or formed in some embodiments.

Referring to FIGS. 6, 7D, and 7E, isolation layers are formed overlying the substrate 708. FIG. 7D is a block diagram illustrating a top view of NVM device 700 and FIG. 7E illustrates a representative vertical cross-sectional view along cutting plane A-A of FIG. 7D. In one embodiment, isolation nitride layer 714 may be formed by any suitable deposition methods known in the art, including but not limited to chemical vapor deposition (CVD), atomic layer deposition (ALD), molecular beam epitaxy (MBE), to an approximate thickness of 5 nm to 40 nm. Isolation nitride layer may include silicon nitride formed overlying lower S/D regions 702 and isolation regions 704 in substrate 708, or overlying pad oxide if present. Next, isolation oxide layer 712 is formed overlying isolation nitride layer to a thickness in an approximate range of 50 nm to 300 nm. Isolation oxide layer 712 may include silicon oxide or oxynitride formed by any suitable deposition methods known in the art, such as CVD, PVD, ALD, and MBE.

Next, vertical openings 710, which are substantially perpendicular to the plane of substrate 708, may be formed in locations where vertical channels of each NVM cells 706 may be subsequently formed. In one embodiment, there may be vertical openings 710 and each is formed within its corresponding lower S/D region 702 in substrate 708. It is the understanding that the vertical axis of vertical openings 710 may be disposed at a right angle (90°) or an approximate right angle to the top surface of substrate 708. As best shown in FIG. 7D, vertical openings 710 may be formed by etching isolation oxide layer 712 and isolation nitride layer 714, and stopped at the top surface of lower S/D region 702, using suitable etching processes, such as plasma etching, wet etching, or other etching methods known in the art. In one embodiment, vertical openings 710 provide a space to fabricate NVM cell 706 therein in subsequent process steps. By configuring the depth of vertical openings 710 or the thickness of isolation layers 712 and 714, channel length of NVM cell 706 may be controlled.

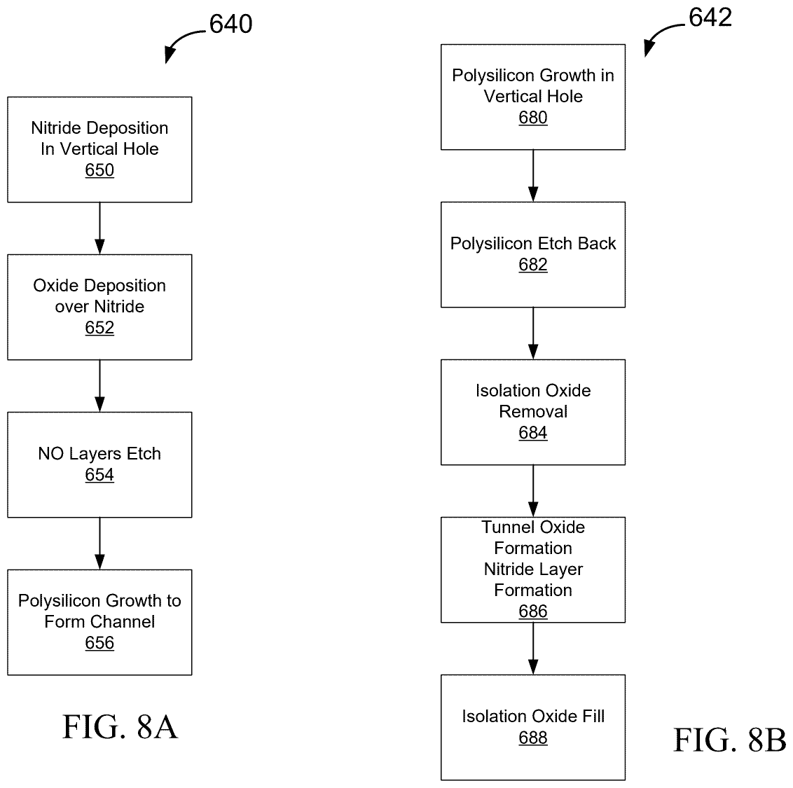

Next, referring to FIG. 6, vertical channel and gate dielectric layer or ON stack are formed within vertical openings 710 (step 610). In one embodiment, vertical channels may be formed after the ON stacks, in a channel last process flow 640 as described in FIGS. 7H, 7G, and 8A. In another embodiment, vertical channels may be formed before the ON stacks, in a channel first process flow 642 as described in FIG. 8B, and 9A-9D. One having ordinary skill in the art would comprehend that, regardless of the sequence of vertical channel and ON stack formation, it would yield the final structure of NVM cells 706, as best shown in FIG. 7P.

FIG. 7F-7K and 7M-7N illustrates a vertical cross-sectional view along cutting plane A-A of FIG. 7D, as the fabrication process progresses. It will be the understanding that, only two NVM cells 706 similar to C121 and C122 in FIG. 4, that share a single word line (WL1) and bit line (BL2), and coupled with adjacent source line (SL1 and SL2) are shown as examples of NVM devices fabricated by the process flow of the present disclosure. Other NVM cells 706 in the NVM device 700 may adopt similar process flow and be fabricated concurrently or subsequently. In one embodiment, a memory film stack in the form of ONO stack is used as an example of NVM devices fabricated by the process flow of the present disclosure. One having ordinary skill in the art would understand that NVM devices having other memory film stack, such as the ferroelectric film stack (with or without the interfacial layer), may be fabricated with the same process flow with slight adjustments.

### ON (Memory Film Stack) First/Channel Last Process Flow

Referring to FIGS. 8A and 7F, charge-trapping layer 718 and tunnel oxide or dielectric layer 716 are formed within vertical opening 710 (steps 650 and 652). In various embodiments, charge-trapping layer 718 is a single layer and may include a layer of silicon nitride and/or silicon oxynitride formed on or overlying or in contact with side surface of vertical opening 710. The charge-trapping layer 718 may be formed by suitable conformal deposition process, such as CVD and ALD. In one embodiment, charge-trapping layer 718 may have a relatively uniform thickness of from about 30 Å to about 100 Å or other thicknesses. After the deposition process, charge-trapping layer 718 is a continuous layer, or coating the entire length of vertical opening 710, including the bottom (not shown in FIG. 7F). In one embodiment, charge-trapping layer 718 may trap charge carriers during operations of NVM cell 706. As explained in previous sections associated with FIG. 5A, charge-trapping layer 718 may include one or more spatially separated regions in which charge carriers are trapped, in order to retain more than one or more bit of binary data, or multiple level data. In other embodiments, charge-trapping layer 718 may include multiple layers of silicon oxynitride that have a stoichiometric ratio of oxygen, nitrogen and/or silicon that are different from one another. Next, tunnel dielectric layer 716 is formed in vertical opening 710, in step 652. In one embodiment, tunnel dielectric layer 716 may be formed on or overlying or in contact with the charge-trapping layer 718 within vertical opening 710. For example, a layer of dielectric material may be deposited by CVD or ALD process conformally over charge-trapping layer 718, or thermally grown. In various embodiments, the layer of dielectric material may include, but not limited to silicon dioxide, silicon oxynitride, silicon nitride, aluminum oxide, hafnium oxide, zirconium oxide, hafnium silicate, zirconium silicate, hafnium oxynitride, hafnium zirconium oxide and lanthanum oxide. Generally, tunnel dielectric layer 716 has a relatively uniform thickness of from about 20 Å to about 70 Å or other thicknesses suitable to allow charge carriers to tunnel into the charge-trapping layer 718 under an applied control gate bias while maintaining a suitable barrier to leakage when the applied gate is unbiased. In certain embodiments, tunnel dielectric layer 716 is silicon dioxide, silicon oxynitride, or a combination thereof and can be grown by a thermal oxidation process, using plasma or radical oxidation of a top portion of charge-trapping layer 718.

Next, the process of multi-layer punch or etch is performed, in step 654. In one embodiment, the multi-layer punch may be performed to remove a portion of the NO stack disposed at the bottom of vertical opening 710. As best shown in FIG. 7F, an etching process is performed to remove tunnel dielectric 716 and charge-trapping 718 layers previously formed at the bottom of vertical opening 710. In one embodiment, plasma etch process is performed until the bottom of vertical opening 710 at least reaches or gouges into lower S/D region 702. Etchants 711 may include fluorine-based chemicals, such as CF₄, C₄F₆, CH₂F₂, NF₃, and O₂ and Ar, or others practiced in the art. In one embodiment, the multi-layer punch is performed to until lower S/D region 702 is exposed.

Next, referring to FIGS. 8A and 7G, vertical channels 720 are formed within and to fill out vertical openings 710, in step 656. As an example and described earlier, NVM cells 706 are n-channel or n-type device. Therefore, vertical channels 720 include semiconductor material with p-type dopants, such as boron ions. In one embodiment, vertical channel 720 is formed at the bottom of vertical opening 710 and overlying lower S/D region 702. Vertical channel 720 may be composed of single crystal silicon or polysilicon, fabricated using selective epitaxial growth (SEG) techniques in which growth may occur on exposed silicon areas of substrate 708. Regions on which silicon growth is not desired may be masked by a dielectric film, typically silicon dioxide or silicon nitride. Silicon grown in the SEG process may be undoped. Subsequently, undoped vertical channel 720 may be implanted with p-type dopants using doping techniques practice in the art. Alternatively, SEG grown silicon may be doped. In some embodiments, silicon grown in vertical channel 720 may be positively doped, negatively doped, and the doping may be in-situ doping. Doping of vertical channel 720, if performed, may be carried out either during the SEG step or after. Since positively doped vertical channel 720 is in direct contact with heavily and negatively doped lower S/D region, n-type dopants in lower S/D region may diffuse upwardly and create an intervening structure, lower S/D buffer 730, that is lightly doped with negative implants.

Next, referring to FIGS. 6 and 7G, upper S/D regions or junctions of NVM cells are formed, in step 612. As best shown in FIG. 7G, vertical channel 720 is grown until it fills out vertical opening 710 and form a circular overhang such that tunnel dielectric 716 and charge-trapping 718 layers are not exposed. In one embodiment, the circular overhang is not removed and a thin oxide layer 722 is formed over its surface by oxidation or deposition process(es) known and practiced in the art. Subsequently, the circular overhang is implanted heavily through thin oxide layer 722 with n-type dopants 724. The dopants 724 implanted may be of any type and concentration, and may be implanted at any energy, including energies necessary to form heavily doped negative implant (N+ implant). Negative dopant implants 724 may include arsenic ions, phosphorus ions. Consequently, the circular overhang is heavily doped to form upper S/D region or junction 726 for NVM cell 706. Similarly, since the positively doped vertical channel 720 is in direct contact with heavily and negatively doped upper S/D region 726, n-type dopants in upper S/D region 726 may diffuse downwardly and create an intervening structure, upper S/D buffer 728, that is lightly doped with negative implants.

In one alternative embodiment, as best shown in FIG. 7H, the circular overhang created during the formation of vertical channel 720 is etched down with a portion of tunnel dielectric 716 and charge-trapping 718 layers that creates opening 729. In embodiments, suitable etching processes, such as plasma etching, wet etching, and others, may be adopted. As best shown in FIG. 7I, a layer of S/D silicon 726′ is formed to fill out opening 729. In embodiments, S/D silicon 726′ may be formed by any suitable deposition process, such as low pressure chemical vapor deposition (LPCVD), CVD and ALD, or other deposition process(es) practiced in the art. Subsequently, S/D silicon 726′ is implanted heavily with n-type dopants 724. The dopants 724 implanted may be of any type and concentration, and may be implanted at any energy, including energies necessary to form heavily doped negative implant (N+ implant). Negative dopant implants 724 may include arsenic ions, phosphorus ions. Alternatively, S/D silicon 726′ may also be formed using SEG grown silicon with in-situ doping of appropriate type(s). Consequently, the S/D silicon 726′ is heavily doped to form upper S/D region or junction 726 for NVM cell 706. Similarly, since the positively doped vertical channel 720 is in direct contact with heavily and negatively doped upper S/D region 726, n-type dopants in upper S/D region 726 may diffuse downwardly and create an intervening structure, upper S/D buffer 728, that is lightly doped with negative implants.

### Channel First/ON (Memory Film Stack) Last Process Flow

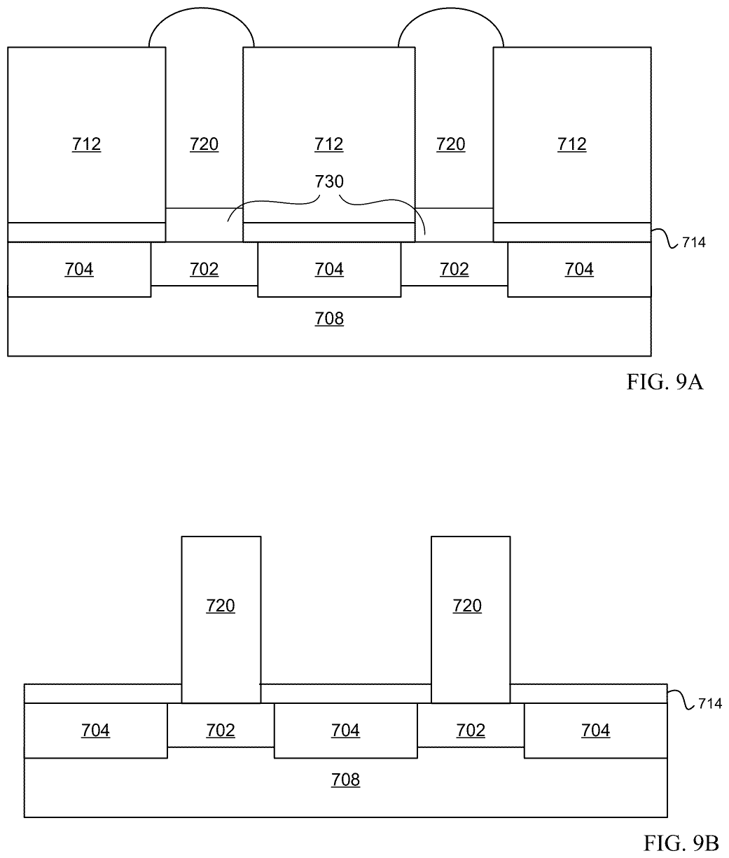

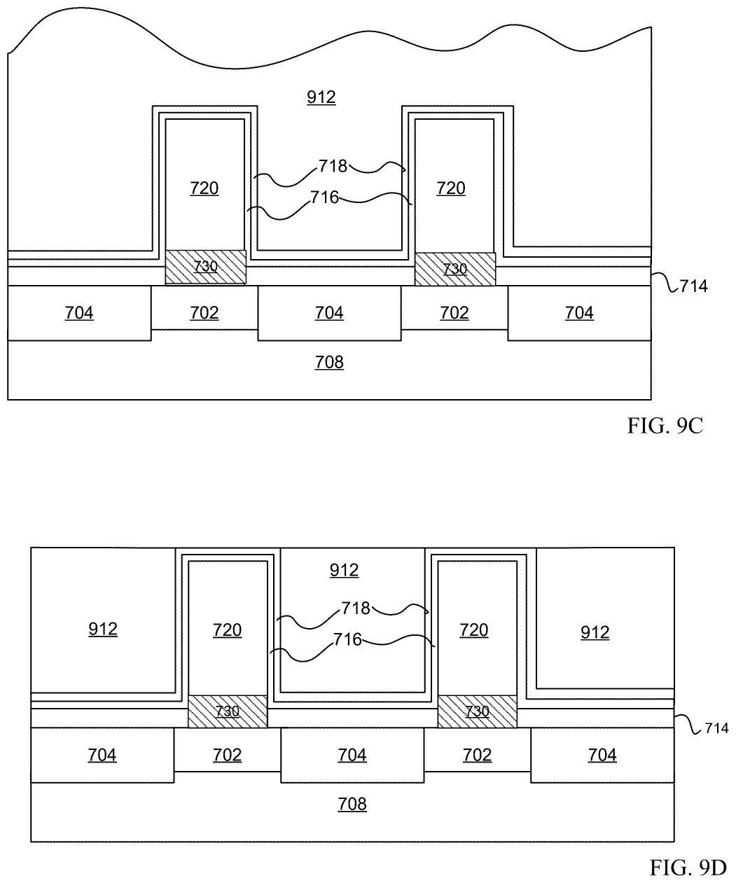

Referring to FIG. 8B, a channel first/ON last process flow 642 begins with silicon growth in vertical openings. As best shown in FIG. 9A, vertical channel 720 is formed within and to fill out vertical openings 710, in step 680. As an example and described earlier, NVM cells 706 are n-channel or n-type device. Therefore, vertical channels 720 include semiconductor material implanted with p-type dopants, such as boron ions. In one embodiment, vertical channel 720 is formed at the bottom of vertical opening 710 and overlying lower S/D region 702. Vertical channel 720 may be composed of single crystal silicon or polysilicon, fabricated using selective epitaxial growth (SEG) techniques in which growth may occur on exposed silicon areas of substrate 708. Regions on which silicon growth is not desired may be masked by a dielectric film, typically silicon dioxide or silicon nitride. In one embodiment, SEG grown silicon is doped. Silicon grown in vertical channel 720 may be positively doped, negatively doped, and the doping may be in-situ doping. Doping of vertical channel 720, if performed, may be carried out either during the SEG step or after. Since positively doped vertical channel 720 is in direct contact with heavily and negatively doped lower S/D region 702, n-type dopants in lower S/D region 702 may diffuse upwardly and create an intervening structure, lower S/D buffer 730, that is lightly doped with negative implants. As best shown in FIG. 9A, vertical channel 720 is grown until it forms a circular overhang over vertical opening 710.

Next, circular overhang of vertical channel 720 is etched back, in step 682. The etching process may be plasma etch or CMP. As best shown in FIG. 9B, after the circular overhang is removed, isolation oxide layer 712 is removed, in step 684. Isolation oxide layer 712 may be removed by plasma etching, wet etching, or other etching process(es) practiced in the art. The etching process stop at isolation nitride layer 714 and vertical channel 720.

Referring to FIGS. 8B and 9C, tunnel dielectric layer and charge-trapping layer are formed overlying substrate 708, in step 686. In one embodiment, tunnel dielectric layer 716 is formed conformally overlying isolation nitride layer 714 and exposed surface of vertical channel 720. For example, a layer of dielectric material may be thermally grown, or deposited by CVD or ALD process conformally over the entire substrate 708. In various embodiments, the layer of dielectric material may include, but not limited to silicon dioxide, silicon oxynitride, silicon nitride, aluminum oxide, hafnium oxide, zirconium oxide, hafnium silicate, zirconium silicate, hafnium oxynitride, hafnium zirconium oxide and lanthanum oxide. Generally, tunnel dielectric layer 716 has a relatively uniform thickness of from about 20 Å to about 70 Å or other thicknesses suitable to allow charge carriers to tunnel into the charge-trapping layer 718 under an applied control gate bias while maintaining a suitable barrier to leakage when the applied gate is unbiased. Next, in various embodiments, charge-trapping layer 718 is a single layer and may include a layer of silicon nitride and/or silicon oxynitride formed on or overlying or in contact with tunnel dielectric layer 716. The charge-trapping layer 718 may be formed by suitable conformal deposition process, such as CVD and ALD. In one embodiment, charge-trapping layer 718 may have a relatively uniform thickness of from about 30 Å to about 100 Å or other thicknesses. After the deposition process, charge-trapping layer 718 is a continuous layer overlying tunnel dielectric layer 716. In one embodiment, charge-trapping layer 718 may trap charge carriers during operations of NVM cell 706. As explained in previous sections associated with FIG. 5A, charge-trapping layer 718 may include one or more spatially separated regions in which charge carriers are trapped, in order to retain more than one or more bit of binary data, or multiple level data. In other embodiments, charge-trapping layer 718 may include multiple layers of silicon oxynitride that have a stoichiometric ratio of oxygen, nitrogen and/or silicon that are different from one another. Next, still referring to FIGS. 8B and 9C, a second isolation oxide layer 912 may be similar to isolation oxide layer 712, as best shown in FIG. 9A, is formed overlying all features on or within substrate 708. Second isolation oxide layer 912 may include silicon oxide and formed by deposition processes such as CVD and ALD. Next, as best shown in FIG. 9D, second isolation oxide layer 912 is subsequently planarized using CMP or similar process(es) until at least charge-trapping layer 718 overlying vertical channel 720 is exposed.

In one embodiment, the process flow of channel first/ON last embodiment may advance to step 612 of FIG. 6, wherein upper S/D regions may be formed. As previously explained, a portion of vertical channel 720, tunnel dielectric 716 and charge-trapping 718 layers are etched down that creates opening 729. As best shown in FIG. 7I, a layer of S/D silicon 726′ is formed to fill out opening 729. In embodiments, S/D silicon 726′ may be formed by any suitable deposition process, such as low pressure chemical vapor deposition (LPCVD), CVD and ALD, or other deposition process(es) practiced in the art. Subsequently, S/D silicon 726′ is implanted heavily with n-type dopants 724. The dopants 724 implanted may be of any type and concentration, and may be implanted at any energy, including energies necessary to form heavily doped negative implant (N+ implant). Negative dopant implants 724 may include arsenic ions, phosphorus ions. Alternatively, S/D silicon 726′ may also be formed using SEG grown silicon with in-situ doping of appropriate type(s). Consequently, the S/D silicon 726′ is heavily doped to form upper S/D region 726 for NVM cell 706. Similarly, since the positively doped vertical channel 720 is in direct contact with heavily and negatively doped upper S/D region 726, n-type dopants in upper S/D region 726 may diffuse downwardly and create an intervening structure, upper S/D buffer 728, that is lightly doped with negative implants. It will be the understanding that both channel first/ON last or ON first/channel last process flows would yield a similar device structure, as best shown in FIG. 7G or 7I.

Next, referring to FIGS. 6 and 7J, blocking dielectric layer of NVM cells are formed to complete the ONO stack of NVM cells, in step 614. Although NVM cells 706 having a circular upper S/D region 726 (overhang vertical channel as in FIG. 7G) is shown as an example, it will be the understanding that the following process flow can be adopted by NVM cells 706 not having a circular upper S/D region 726, as best shown in FIG. 7I. In one embodiment, isolation oxide layer 712 or 912 (in channel first/ON last flow) is removed by suitable etching process, such as plasma etch or wet etch. A conformal layer of blocking dielectric layer 732, to a uniform thickness in an approximate range of 30 Å to 100 Å, is formed overlying NVM cells 706 and the rest of substrate 708. In embodiments, blocking dielectric layer 732 may include any material and have any thickness suitable to insulate charge-trapping layer 718 from the gate of NVM cell 706. In some embodiments, blocking dielectric layer 732 may include silicon dioxide, silicon oxy-nitride, or a combination thereof and may be grown by a thermal oxidation process, using ISSG or radical oxidation, or conventional deposition processes, such as CVD and ALD, known in the art. In embodiments, there may be a high dielectric constant or high-K dielectric material or layer formed or deposited on or over blocking dielectric layer 732. The high-K dielectric layer (not shown) may include, but is not limited to, aluminum oxide, hafnium oxide, zirconium oxide, hafnium silicate, hafnium oxy-nitride, hafnium zirconium oxide and lanthanum oxide deposited to a physical thickness between about 1 nm and about 5nm or other thicknesses by, for example, atomic layer deposition (ALD), physical vapor deposition (PVD), a chemical vapor deposition (CVD), a low pressure CVD (LPCVD) or a plasma enhanced CVD (PECVD) process. Optionally, NVM device 700 will then undergo annealing as practiced by one having ordinary skill in the art.

Next, referring to FIGS. 6 and 7K, metal gate/word line is formed around NVM cells, in step 616. As best shown in FIG. 7K, a layer of conductive material, such as tungsten (W), is formed using a metal CVD process overlying and encapsulating NVM cells 706. In embodiments, metal gate layer 734 may include different conductive materials including but are not limited to metal nitrides, metal carbides, metal silicides, hafnium, zirconium, titanium, tantalum, aluminum, ruthenium, tungsten, palladium, platinum, cobalt, and nickel, which are known in the art and may be adopted.

FIG. 7L is a representative block diagram illustrating a vertical cross-sectional view of NVM device 700 along the cutting plane B - B of FIG. 7A, at this point of fabrication process after metal gate layer 734 is formed. As best shown in FIG. 7L, two NVM cells 706 coupled to the same word line and source line (similar to C121 and C111 of FIG. 4). In one embodiment, metal gate layer 734 functions both as metal gate to provide biasing voltages to individual NVM cells 706 and a word line coupling multiple NVM cells 706 in one direction. In one embodiment, metal gate layer 734 is planarized and etched back to expose upper S/D regions 726 and laterally to encapsulate all NVM cells 706 of the same WL within a predetermined WL width.

FIG. 7M is a representative block diagram illustrating a top view of NVM device 700. FIG. 7N illustrating a vertical cross-sectional view along cutting plane A-A of FIG. 7M, showing two adjacent NMM cells along or coupled to the same BL (e.g. BL2 in FIG. 4) and WL (e.g. WL1). Referring to FIGS. 6 and 7M-7N, upper S/D region contacts or BL connects are formed to couple NVM cells of the same BL, in step 618. After metal gate layer 734 is patterned to form a WL coupling NVM cells at their respective gates (e.g. C111, C121, C122, C132 in FIG. 4), isolation layer 736 is formed and subsequently etched back and/or planarized to cover or encapsulate all NVM cells 706. Isolation layer 736 may include silicon oxide that is formed by a deposition process, oxidation process, or a combination thereof. In one embodiment, an elongated S/D contact opening 738 is created in isolation layer 736 by an etching process, such as plasma etching and wet etching. As best shown in FIG. 7M, the elongated S/D contact opening 738 is disposed between two adjacent NVM cells 706. The etch process may include one or more separate steps, including patterning photoresist mask or hard mask, multiple etching with different etchants, being configured to expose the conducting or conductive upper S/D regions 726 of the two NVM cells 706.

Referring to FIGS. 6 and 7O-7P, BLs are formed to coupled multiple NVM cells, in step 620. FIG. 7O is a representative block diagram illustrating a top view of NVM device 700 after BLs 740 are formed. FIG. 7P illustrating a vertical cross-sectional view along cutting plane A-A of FIG. 7O, showing two adjacent NMM cells (e.g. C121 and C122) along or coupled to the same BL (e.g. BL2 in FIG. 4). In one embodiment, S/D contact opening 738 is filled by a layer of conductive materials, such as tungsten, to form BL connect 742. BL connect 742 may be formed by a metal CVD process, followed by an etch back or CMP process to a planarized top surface. Other combinations using different conductive materials to form BL connect 742 may include but are not limited to metal nitrides, metal carbides, metal silicides, hafnium, zirconium, titanium, tantalum, aluminum, ruthenium, tungsten, palladium, platinum, cobalt, and nickel, which are known in the art and may be adopted. Next, a layer of dielectric material, such as silicon oxide, may be form over the entire NVM device 700 such that isolation layer 736′ encapsulate the newly formed BL connect 742 (if present). BL trenches will then be created in isolation layer 736′ to a depth to expose or at least reach BL connect 742 underneath, if present as best shown in FIG. 7P. BL trenches may be formed by patterning a photoresist or hard mask using standard lithographic techniques and plasma etch or other etching processes practiced in the art to remove silicon oxide in isolation layer 736′. In one embodiment, BL trenches are elongated structures running perpendicularly to SLs 702 (or S/D regions) to provide connection to upper S/D regions of NVM cells 706 along the same BL 740. Next, BL trenches are filled by a layer of conductive materials, such as copper or tungsten, to form multiple BLs 740. BLs 740 may be formed by a metal plating or CVD process, and followed by an etch back or CMP process to planarize a top surface. Other combinations using different conductive materials to form BLs 740 may include but are not limited to metal nitrides, metal carbides, metal silicides, hafnium, zirconium, titanium, tantalum, aluminum, ruthenium, copper, tungsten, palladium, platinum, cobalt, and nickel, which are known in the art and may be adopted. As best shown in FIG. 7P, NVM cells 706 (C121 and C122) are coupled to the same BL (e.g. BL2) through upper S/D regions 726 and BL connect 742, which like BL 740 are made of conductive material and in direct contact with one another. For example, when an electrical pulse or a voltage bias is asserted in BL2, the same voltage bias will be transmitted to NVM cells C121 and C122 via BL connect 742. As best shown in FIG. 7P, NVM cells 706 of NVM device 700 may be arranged in one single layer and all may be disposed vertically between BLs and SLs.

In one embodiment, the NVM device having vertical channels, such as NVM array 200 or NVM device 700 are substantially completed. It will be the understanding that, although only a portion of NVM device 700 is shown, similar devices having multiple and various quantities of WLs 734, BLs 740, SLs 702, NVM cells 706 may be fabricated using the process flows illustrated at least in FIG. 6 - 9D and their corresponding description. It will also be the understanding that, one or more NVM cells 706 in NVM device 700 may be formed concurrently or consecutively using the aforementioned process flows. Finally, the standard or baseline CMOS process flow is continued to substantially complete the back end device fabrication (step 622).

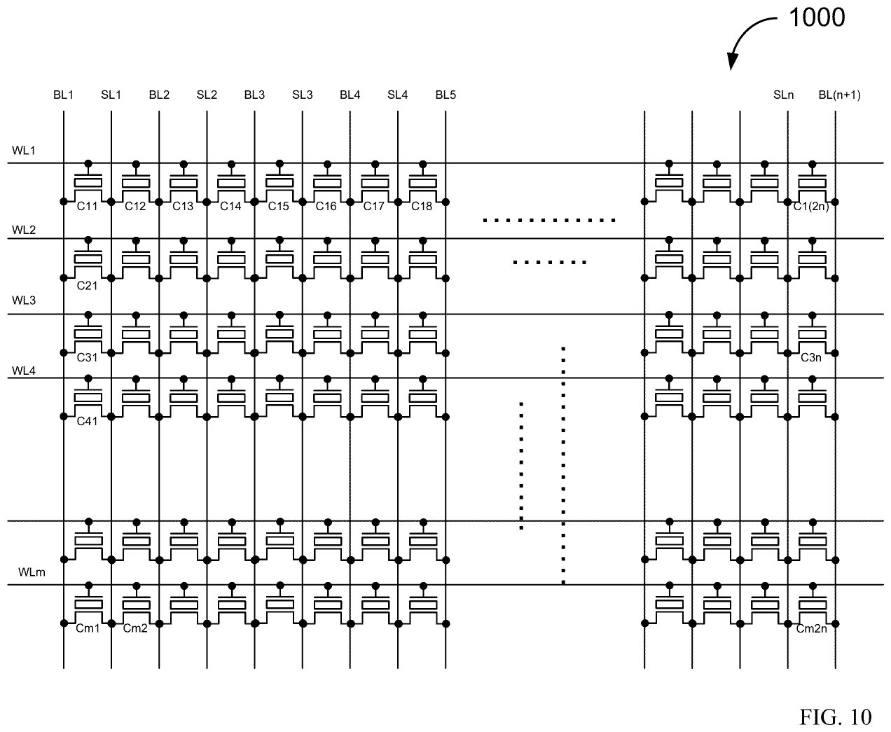

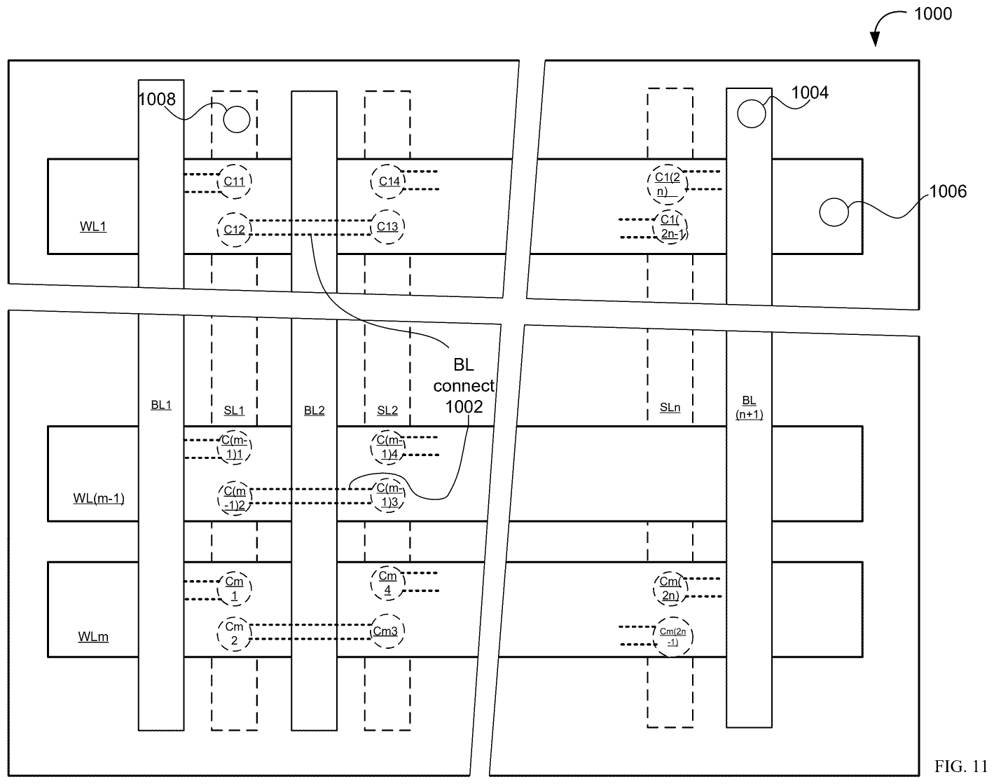

FIG. 10 is a schematic block diagram illustrating an NVM array 1000 having m x WLs, n×SLs, and (n+1) BLs. FIG. 11 is a representative block diagram illustrating a top view of NVM array 1000 of FIG. 10, or similar NVM arrays, such as NVM array 200 and NVM device 700. In one embodiment, NVM array 1000, which is similar to NVM array 200 in FIG. 4 and NVM device 700 in FIG. 7P, includes m rows and 2n columns of NVM cells, or 2n rows and m columns, depending on the orientation of NVM array 1000. NVM cells are similarly fabricated and structured as NVM cells 706, each including a vertical channel 720 connecting a lower S/D region (SL) 702 in the substrate and an upper S/D region 726 (to BL 740). In some embodiments, NVM cells may be bi-directional devices and store two physical bits in the charge trapping layer, such as charge trapping layer 718 in FIG. 7N, in which SL and BL are interchangeable functionally. These two independent physical bits (bit1 and bit2) can be independently read by running a current through vertical channel 720 in different directions (up or down), or other read/sensing algorithms known by one having ordinary skill in the art. In embodiments, each NVM cell may store one or multiple bits of binary data, corresponding to charges trapped in one or more spatially separated locations in the charge trapping layer of the NVM cell. Referring to FIG. 10, in a single row of NVM cells connected to a single WL, for example WL1, there are 2n NVM cells (C11-C1(2n)). In a single column of NVM cells, wherein each NVM cell is coupled to the same BL and SL (e.g. BL1 and SL1), there are m×NVM cells (C11-Cm1). In this particular embodiment, there are a total of (m×2n) NVM cells in NVM array 1000, wherein adjacent cells (e.g. C12 and C13) of the same row may share either one BL or one SL.

Referring to FIG. 11, SLs and BLs are arranged to extend or propagate in the same direction (vertically as shown in FIG. 11), whereas WLs are arranged to extend or propagate in a perpendicular direction (horizontally) to both SLs and BLs. Each NVM cell is fabricated overlying its corresponding SL, which as previously explained, also functions as lower S/D region providing electrical signals or bias to one end or the lower end of NVM cells. The upper end or upper S/D region of each NVM cell is coupled to its corresponding BL via BL connect 1002. In one embodiment, NVM cells are arranged in one single layer and disposed vertically between SLs and BLs. In embodiments, BLs provide electrical signals or bias to the upper end of NVM cells at each of their upper S/D regions. WLs are formed vertically between SL (within or buried in substrate) and BLs, surrounding the ONO stack and vertical channel of each NVM cell. In embodiments, WLs function as the gate for each of its respective NVM cell, providing the same electrical signal and bias to each NVM cell along one WL. As best shown in FIG. 11, there are WL contact 1006, SL contact 1008, and BL contact 1004 in one or more WLs, SLs, and BLs, respectively. Contacts 1004, 1006, 1008 are configured to provide an interface to receive or transmit electrical signal, pulse, or bias from or to circuits outside NVM array 1000. Electrical signals received through WL contact 1006 of WL1 will be provided to gates of NVM cells C11, C12, . . . , C1(2n) of row 1. Similarly, electrical signals received through SL contact 1008 of SL1 will be provided to lower S/D regions of NVM cells C11, C12, . . . Cm1, Cm2 of columns 1 and 2 of NVM array 1000. Electrical signals received through BL contact 1004 of BL1 will be provided to upper S/D regions of NVM cells C11, C21, . . . Cm1 of column 1 of NVM array 1000.

Thus, embodiments of a non-volatile memory having vertical channels and methods of fabricating the same have been described. Although the present disclosure has been described with reference to specific exemplary embodiments, it will be evident that various modifications and changes may be made to these embodiments without departing from the broader spirit and scope of the disclosure. Accordingly, the specification and drawings are to be regarded in an illustrative rather than a restrictive sense.

The Abstract of the Disclosure is provided to comply with 37 C.F.R. § 1.72(b), requiring an abstract that will allow the reader to quickly ascertain the nature of one or more embodiments of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

Reference in the description to one embodiment or an embodiment means that a particular feature, structure, or characteristic described in connection with the embodiment is included in at least one embodiment of the circuit or method. The appearances of the phrase one embodiment in various places in the specification do not necessarily all refer to the same embodiment.

What is claimed is:

1. A semiconductor device, comprising:
a non-volatile memory (NVM) transistor form over a substrate, including:
a lower source/drain (S/D) junction buried at least partly in the substrate;
an upper S/D junction;
a vertical channel having a cylindrical shape disposed between the upper and lower S/D junctions;
a cylindrical memory film stack surrounding the vertical channel; and
a gate layer disposed around the memory film stack;
a word line (WL) extending and coupling to gate layers of at least one NVM transistors in a first direction, wherein the gate layers of the at least one NVM transistors in the first direction form a portion of the WL;
a source line (SL) extending and coupling to lower S/D junctions of at least one NVM transistors in a second direction, wherein the lower S/D junctions of the at least one NVM transistors in the second direction form a portion of the SL; and
a bit line (BL) extending and coupling to upper S/D junctions of at least one NVM transistors in the second direction, wherein the first and second directions are substantially perpendicular to one another.

2. The semiconductor device of claim 1, wherein the vertical channel and the memory film stack are disposed uprightly from a top surface of the substrate.

3. The semiconductor device of claim 1, wherein the vertical channel has a circular cross-section and includes at least one of doped polysilicon or single-crystal silicon of a positive type, and wherein the lower and upper S/D junctions include at least one of doped polysilicon or single-crystal silicon of a negative type.

4. The semiconductor device of claim 3, wherein the vertical channel further comprises a channel filler including a dielectric layer surrounded by an outer channel shell including at least one of doped polysilicon or single-crystal silicon of a positive type.

5. The semiconductor device of claim 1, wherein the memory film stack includes:
a tunnel dielectric layer disposed adjacent to the vertical channel;
a charge-trapping layer including at least one layer of silicon nitride or silicon oxynitride; and
a blocking dielectric layer disposed overlying the charge-trapping layer.

6. The semiconductor device of claim 1, wherein the memory film stack includes a ferroelectric film.

7. The semiconductor device of claim 5, wherein the charge-trapping layer is configured to retain electrical charges in more than one physically and spatially separated regions, and wherein the NVM transistors are configured to store more than one bits of binary values.

8. The semiconductor device of claim 1, wherein the BL is coupled to the upper S/D junction of the NVM transistor via a BL connect, wherein the BL connect couples two neighboring NVM transistors to the BL.

9. The semiconductor device of claim 8, wherein the two neighboring NVM transistors are respectively coupled to two neighboring SLs, wherein the two neighboring SLs are electrically insulated from one another.

10. The semiconductor device of claim 1, wherein the semiconductor device is a bi-directional transistor device, and wherein the lower and upper S/D junctions are configured to function as both a source or a drain of the bi-directional transistor device.

11. The semiconductor device of claim 5, wherein the blocking dielectric layer is surrounded by a high-K dielectric layer and the gate layer includes a layer of tungsten, making the semiconductor device a high-K metal gate (HKMG) device.

12. A non-volatile memory (NVM) array, including:
a plurality of source lines (SLs) buried within a substrate extending in a first direction, wherein adjacent SLs are insulated by shallow trench isolations (STIs);
NVM transistors formed overlying the plurality of SLs, each NVM transistor comprising a lower source/drain (S/D) junction, a vertical channel surrounded by a memory film stack and a metal gate layer, and an upper S/D junction overlying the vertical channel;
a plurality of word lines (WLs) coupling to the metal gate layers of at least one NVM transistors and extending in a second direction, wherein the second direction is substantially perpendicular to the first direction; and
a plurality of bit lines (BLs) overlying the upper S/D junctions and the metal gates of the NVM transistors, wherein the BLs are coupled to the upper S/D junctions of at least one NVM transistors and extend in the first direction.

13. The NVM array of claim 12, wherein the plurality of SLs includes doped at least one of polysilicon or single-crystal silicon, and wherein lower S/D junctions of NVM transistors disposed overlying a same SL form a portion of the same SL.

14. The NVM array of claim 12, wherein the plurality of WLs includes a metal layer, and wherein metal gates of NVM transistors coupled by a same WL formed a portion of the same WL.

15. The NVM array of claim 12, wherein first and second NVM transistors are formed overlying two neighboring SLs, wherein upper S/D junctions of the first and second NVM transistors are coupled to a same BL via a horizontal BL connect.

16. The NVM array of claim 12, wherein the memory film stack includes:
a tunnel dielectric layer disposed adjacent to the vertical channel;
a charge-trapping layer including at least one layer of silicon nitride or silicon oxynitride configured to retain electrical charges in more than one physically and spatially separated regions therein; and
a blocking dielectric layer including a layer of high-K dielectric disposed overlying the charge-trapping layer.

17. The NVM array of claim 12, wherein the vertical channel further comprises a channel filler including a dielectric layer surrounded by an outer channel shell including at least one of doped polysilicon or single-crystal silicon of a positive type, and wherein the lower and upper S/D junctions include at least one of polysilicon or single-crystal silicon doped with implant of a negative type.

18. A semiconductor device, comprising:
a plurality of non-volatile memory (NVM) transistors arranged in rows and columns formed in a substrate, wherein each NVM transistor comprises a lower source/drain (S/D) junction, a vertical channel surrounded by a memory film stack and a metal gate layer, and an upper S/D junction overlying the vertical channel;
a plurality of word lines (WLs), each coupling NVM transistors of a same row, wherein metal gate layers of the NVM transistors of the row form a portion of the WLs;
a plurality of source lines (SLs), each coupling NVM transistors of two adjacent columns, wherein lower S/D junction of the NVM transistors of the two adjacent columns form a portion of the SLs; and
a plurality of bit lines (BLs), each coupling NVM transistors of at least one column via a plurality of BL connects;
wherein the plurality of NVM transistors are formed overlying the plurality of SLs formed at least partly within the substrate, the plurality of SLs and BLs propagate in a same direction, and the plurality of WLs and BLs propagate in a perpendicular direction.

19. The semiconductor device of claim 18, wherein NVM transistors that are formed overlying a same SL are coupled to two adjacent BLs, respectively; and wherein the plurality of NVM transistors are arranged in one single layer and vertically disposed between the BLs and SLs.

20. The semiconductor device of claim 18 is a NOR flash memory device, wherein the memory film stack includes:
a tunnel dielectric layer disposed adjacent to the vertical channel;
a charge-trapping layer including at least one layer of silicon nitride or silicon oxynitride configured to retain electrical charges in more than one physically and spatially separated regions; and
a blocking dielectric layer disposed overlying the charge-trapping layer.
